(19) United States
(12) Patent Application Publication
(10) Pub. No.: US 2014/0027762 A1
(43) Pub. Date: Jan. 30, 2014

(54) SEMICONDUCTOR DEVICE

(71) Applicant: Semiconductor Energy Laboratory Co. Ltd., Atsugi-shi (JP)

(72) Inventors: Takuya TSURUME, Isehara (JP); Hideomi Suzawa, Atsugi (JP)

(21) Appl. No.: 13/942,866

(22) Filed: Jul. 16, 2013

(30) Foreign Application Priority Data
Jul. 27, 2012 (JP) 2012-166568

(51) Int. Cl. H01L 29/24

(52) U.S. Cl. CPC H01L 29/24
USPC 257/43

(57) ABSTRACT

A semiconductor device is provided, which includes a first oxide semiconductor layer over a substrate, a second oxide semiconductor layer over and in contact the first oxide semiconductor layer, a source electrode and a drain electrode over the second oxide semiconductor layer, a gate insulating layer over the second oxide semiconductor layer, and a gate electrode over the gate insulating layer. The first oxide semiconductor layer has a step portion. The step portion is thinner than a portion other than the step portion. A surface of the step portion is in contact with the source electrode and the drain electrode.

### BACKGROUND OF THE INVENTION

1. Field of the Invention

One embodiment of the present invention relates to a semiconductor device.

In this specification, a semiconductor device refers to a device which can function by utilizing semiconductor characteristics; a transistor, a semiconductor circuit, an electro-optical device, and an electronic device are all included in the category of the semiconductor device.

2. Description of the Related Art

In recent years, attention has been focused on a transistor in which an oxide semiconductor film is used to form an active layer (at least a region where a channel is formed).

For example, a transistor in which an oxide semiconductor film of amorphous oxide containing indium (In), gallium (Ga), and zinc (Zn) or the like is used to form an active layer (at least a region where a channel is formed) is disclosed (see Patent Document 1).

Research has been conducted on the use of a transistor in which an oxide semiconductor film is used as an active layer, not only in a portion with a relatively large design size, such as a pixel transistor in a liquid crystal display device, an EL display device, or the like, but also in a portion with a small design size, such as a transistor in an integrated circuit, e.g., LSI, CPU, or the like.

The transistor used in the integrated circuit such as LSI or CPU is required to have characteristics such as higher on-off ratio (hereinafter referred to as ON/OFF ratio) and higher field-effect mobility than the transistor used as a pixel transistor or the like.

To fill the requirements for the above-described characteristics of the transistor in which the oxide semiconductor film is used as the active layer, Patent Document 2 discloses a structure in which a resistive layer with lower electrical conductivity than an active layer is formed between the active layer where a channel is formed and source and drain electrodes.

Note that Patent Document 2 states that an oxide semiconductor material (specifically, oxide containing In, oxide containing In and Zn, or oxide containing In, Ga, and Zn) is preferably used for the active layer and the resistive layer.

### REFERENCE

[Patent Document 1] Japanese Published Patent Application No. 2006-165527
[Patent Document 2] Japanese Published Patent Application No. 2008-276212

### SUMMARY OF THE INVENTION

In the case of a transistor with the above-described structure in Patent Document 2, field-effect mobility is reduced because carriers which move between the source electrode and the drain electrode need to pass through the resistive layer having lower electrical conductivity than the active layer (for example, in FIG. 3 of Patent Document 2, carriers injected from a source electrode (or a drain electrode) pass through a resistive layer, an active layer, and the resistive layer in this order in the semiconductor layer and move to the drain electrode (or the source electrode)).

In view of the above, an object of one embodiment of the present invention is to provide a structure of a semiconductor device with excellent ON/OFF ratio and high field-effect mobility.

The energy gap of a semiconductor layer using an oxide semiconductor material is greater than or equal to 3.0 eV, which is much larger than the band gap of silicon (1.1 eV).

The off-resistance of the transistor (resistance between a source and a drain when the transistor is in an off state) is inversely proportional to the concentration of carriers thermally excited in the semiconductor layer where a channel is formed. Since the band gap of silicon is 1.1 eV even in a state where there is no carrier caused by a donor or an acceptor (i.e., even in the case of an intrinsic semiconductor), the concentration of thermally excited carriers at room temperature (200 K) is approximately 1×10¹¹ cm⁻³.

On the other hand, an oxide semiconductor generally has a large band gap, which is greater than or equal to 3.0 eV. For example, in the case of a band gap of 3.2 eV, the concentration of thermally excited carriers is approximately 1×10⁻⁷ cm⁻³. Since the resistivity is inversely proportional to the carrier concentration, the resistivity of a semiconductor having a band gap of 3.2 eV is 18 orders of magnitude higher than that of silicon even when silicon and the semiconductor have the same electron mobility.

Such a transistor in which an oxide semiconductor material having a wide band gap is used for the semiconductor layer can achieve an extremely small off-state current. For this reason, when a structure of the transistor including the oxide semiconductor is designed to provide increased on-state current and field-effect mobility, the transistor can have excellent ON/OFF ratio and high field-effect mobility.

Hence, in a semiconductor device of one embodiment of the present invention, an oxide semiconductor layer includes a stack of at least a first oxide semiconductor film whose main purpose is to function as a carrier path and a second oxide semiconductor film which is between the first oxide semiconductor film and a gate insulating layer and whose main purpose is to reduce interface state density. With such a structure, carriers which move in the oxide semiconductor layer are less likely to be affected by an interface state generated at the interface between the oxide semiconductor layer and the gate insulating layer (for example, carriers are less likely to be trapped in the interface state or carriers are less likely to be scattered due to trapped carriers).

Note that to suppress the generation of the interface state at the interface between the first oxide semiconductor film and the second oxide semiconductor film, films containing the same metal element as their main component are used as the first oxide semiconductor film and the second oxide semiconductor film.

For example, when In—Ga—Zn-based oxide (i.e., metal oxide containing In, Ga, and Zn as its main components) is used for the first oxide semiconductor film, the In—Ga—Zn-based oxide is also used for the second oxide semiconductor film.

Note that a “main component” in this specification or the like refers to an element contained at 5 atomic % or more in composition.

However, just employing the above-described structure for the semiconductor device might cause a flow of carriers near a surface of the second oxide semiconductor film and an influence of an interface state at the interface between the second oxide semiconductor film and a layer formed thereover (e.g., the gate insulating layer) on the carriers.

Thus, a structure is employed in which the second oxide semiconductor film has electron affinity lower than that of the first oxide semiconductor film by 0.1 eV or more to provide a band offset at the bottoms of the conduction bands of the second oxide semiconductor film and the first oxide semiconductor film, so that carriers selectively flow in the first oxide semiconductor film.

Note that “the second oxide semiconductor film has electron affinity lower than that of the first oxide semiconductor film by 0.1 eV or more” means that the electron affinity (energy difference between the vacuum level and the bottom of the conduction band) of the second oxide semiconductor film is lower than the electron affinity of the first oxide semiconductor film, and energy difference between the bottoms of the conduction bands of the second oxide semiconductor film and the first oxide semiconductor film is 0.1 eV or more. In other words, the bottom of the conduction band of the second oxide semiconductor film is located closer to the vacuum level than the bottom of the conduction band of the first oxide semiconductor film by 0.1 eV or more.

Such a structure reduces the influence of the interface state on carriers moving in the oxide semiconductor layer, which enables the transistor to have good electrical characteristics. For example, field-effect mobility and a subthreshold swing (also referred to as an S value) can be increased.

In addition, to facilitate the movement of carriers from the source electrode (or the drain electrode) to the first oxide semiconductor film, step portions are provided in the first oxide semiconductor film to overlap with the source electrode without overlapping with the second oxide semiconductor film and to overlap with the drain electrode without overlapping with the second oxide semiconductor film; thus, the source electrode and the drain electrode are in contact with bottom surfaces (surfaces which are each between the surface of the first oxide semiconductor film and the surface of the substrate and are substantially parallel to the surface of the substrate) and side surfaces of the step portions.

Consequently, carriers are directly injected from the source electrode (or the drain electrode) and also injected from the side surfaces of the step portions into the first oxide semiconductor film whose main purpose is to function as a carrier path, resulting in an increase in an area where carriers are injected. This enables the transistor to have good electrical characteristics. For example, the field-effect mobility of the transistor or on-state current can be increased.

One embodiment of the present invention is a semiconductor device including an oxide semiconductor layer over an insulating surface; a source electrode and a drain electrode over the oxide semiconductor layer; a gate insulating layer over the oxide semiconductor layer, the source electrode, and the drain electrode; and a gate electrode overlapping with the oxide semiconductor layer with the gate insulating layer provided therebetween. The oxide semiconductor layer includes a first oxide semiconductor film over the insulating surface and a second oxide semiconductor film in contact with and between the first oxide semiconductor film and the gate insulating layer. The first oxide semiconductor film includes a step portion overlapping with the source electrode without overlapping with the second oxide semiconductor film and a step portion overlapping with the drain electrode without overlapping with the second oxide semiconductor film. The second oxide semiconductor film has electron affinity lower than electron affinity of the first oxide semiconductor film by 0.1 eV or more. The first oxide semiconductor film and the second oxide semiconductor film contain the same metal element as a main component. The source electrode and the drain electrode are in contact with bottom surfaces and side surfaces of the step portions.

In a semiconductor device having the above-described structure, an influence of an interface state on carriers moving in the oxide semiconductor layer is reduced, and carriers are also injected from the side surfaces of the step portions into the first oxide semiconductor film, which enables excellent ON/OFF ratio and high field-effect mobility.

Note that in the above-described structure of the oxide semiconductor layer, it is preferable that, in addition to the first oxide semiconductor film and the second oxide semiconductor film, the oxide semiconductor layer include a third oxide semiconductor film between the insulating surface and the first oxide semiconductor film and in contact with the first oxide semiconductor film, and the second oxide semiconductor film and the third oxide semiconductor film each have electron affinity lower than the electron affinity of the first oxide semiconductor film by 0.1 eV or more.

In general, carriers passing through a back channel side selectively flow in the oxide semiconductor layer which is close to the insulating surface (e.g., a surface of an insulating substrate or a surface of an insulating film formed as a base film). On the other hand, with the three-layer structure including the third oxide semiconductor film as described above, a band offset is provided also at the bottoms of the conduction bands in a portion where the first oxide semiconductor film and the third oxide semiconductor film are in contact with each other; thus, carriers passing through a back channel side selectively flow in the first oxide semiconductor film which is close to the interface between the first oxide semiconductor film and the third oxide semiconductor film, and therefore carriers are less likely to be affected by an interface state at the interface between the insulating surface and the oxide semiconductor layer. Consequently, the electrical characteristics of the semiconductor device can be further increased.

In addition, in the above-described structure of the oxide semiconductor layer, it is preferable that a first insulating layer including an oxide insulating film capable of releasing oxygen by heat treatment be over and in contact with the insulating surface, and a second insulating layer including an oxide insulating film capable of releasing oxygen by heat treatment be over and in contact with the source electrode and the drain electrode. That is, the oxide semiconductor layer is preferably surrounded by the first insulating layer and the second insulating layer each including the oxide insulating film capable of releasing oxygen by heat treatment.

When there is oxygen vacancy in the oxide semiconductor layer, the oxygen vacancy causes carriers to be generated, so that the electrical characteristics of the semiconductor device become worse in some cases. For example, in a transistor in which a channel is formed in an oxide semiconductor layer including oxygen vacancy, the channel exists even when a voltage is not applied to a gate electrode, so that a drain current flows in the transistor (i.e., a phenomenon where a transistor becomes normally-on occurs) in some cases.

For this reason, the oxide semiconductor layer is surrounded by the first insulating layer and the second insulating layer each including the oxide insulating film capable of releasing oxygen by heat treatment as in the above-described structure, which makes it possible to supply oxygen to the oxide semiconductor layer by heat treatment and to reduce oxygen vacancy in the oxide semiconductor layer. Thus, deterioration of the electrical characteristics can be further prevented.

In the oxide semiconductor layer with the above-described structure, the first insulating layer includes a first nitride insulating film between the insulating surface and the oxide insulating film, in addition to the oxide insulating film; the second insulating layer includes a second nitride insulating film over the oxide insulating film, in addition to the oxide insulating film. This makes it possible to suppress outward diffusion of oxygen released from the oxide insulating film by heat treatment, and to supply oxygen to the oxide semiconductor layer efficiently. Thus, deterioration of the electrical characteristics can be further prevented.

The oxide semiconductor layer has a stacked-layer structure including at least the first oxide semiconductor film whose main purpose is to function as a carrier path and the second oxide semiconductor film which is provided between the first oxide semiconductor film and the gate insulating film and whose main purpose is to reduce interface state density, the second oxide semiconductor film has electron affinity lower than electron affinity of the first oxide semiconductor film by 0.1 eV or more, and the first oxide semiconductor film and the second oxide semiconductor film contain the same metal element as a main component; thus, an influence of the interface state on carriers moving in the oxide semiconductor layer is reduced, which enables field-effect mobility, a subthreshold swing (S value), or the like to be increased and the transistor to have good electrical characteristics.

Further, the first oxide semiconductor film includes a step portion overlapping with the source electrode without overlapping with the second oxide semiconductor film and a step portion overlapping with the drain electrode without overlapping with the second oxide semiconductor film, and the source electrode and the drain electrode are in contact with bottom surfaces and side surfaces of the step portions. With such a structure, carriers are directly injected from the source electrode (or the drain electrode) into the first oxide semiconductor film whose main purpose is to function as a carrier path, and carriers are injected also from the side surfaces of the step portions into the first oxide semiconductor film, which enables field-effect mobility, on-state current, or the like to be increased and the transistor to have good electrical characteristics.

One embodiment of the present invention can provide a structure of a semiconductor device having excellent ON/OFF ratio and high field-effect mobility.

### BRIEF DESCRIPTION OF THE DRAWINGS

FIGS. 1A to 1C illustrate a structure of a semiconductor device.

FIGS. 2A and 2B each illustrate a feature of a semiconductor device.

FIG. 3 illustrates a structure of a semiconductor device.

FIGS. 4A to 4D illustrate a method for manufacturing a semiconductor device.

FIGS. 5A and 5B illustrate the method for manufacturing the semiconductor device.

FIGS. 6A to 6C illustrate a method for manufacturing a semiconductor device.

FIGS. 7A and 7B illustrate a circuit configuration and a structure of a NAND circuit.

FIG. 8 illustrates a circuit configuration of a NOR circuit.

FIGS. 9A to 9C illustrate a structure of a connection electrode.

FIGS. 10A and 10B each illustrate a circuit configuration of a memory cell.

FIGS. 11A to 11C illustrate a CPU and memory devices.

FIGS. 12A and 12B each illustrate electronic devices.

### DETAILED DESCRIPTION OF THE INVENTION

Embodiments of the invention disclosed in this specification will be described below with reference to the accompanying drawings. Note that one embodiment of the present invention is not limited to the following description, and it is easily understood by those skilled in the art that modes and details disclosed herein can be modified in various ways without departing from the spirit and the scope of the present invention. Therefore, one embodiment of the present invention is not interpreted as being limited to the description of the embodiments described below.

Note that in the following embodiments, the same portions or portions having similar functions are denoted by the same reference numerals in different drawings, and explanation thereof will not be repeated in some cases.

Note that the position, size, range, or the like of each structure illustrated in drawings and the like is not accurately represented in some cases for easy understanding. Therefore, the disclosed invention is not necessarily limited to the position, size, range, or the like as disclosed in the drawings and the like.

Note that in this specification and the like, the term such as “over” does not necessarily mean that a component is placed “directly on” another component. For example, the expression “an oxide semiconductor layer over an insulating surface” can mean that another component is provided between the insulating surface and the oxide semiconductor layer. The same applies to the term “below”.

Functions of a “source” and a “drain” are sometimes replaced with each other when a transistor of opposite polarity is used or when the direction of current flowing is changed in circuit operation, for example. Therefore, the “source” and the “drain” can be replaced with each other in this specification.

Note that in this specification and the like, the term “electrically connected” includes the case where components are connected through an “object having any electric function”. There is no particular limitation on the “object having any electric function” as long as electric signals can be transmitted and received between components that are connected through the object. Examples of the “object having any electric function” are an electrode and a wiring.

In this specification, a term “parallel” indicates that the angle formed between two straight lines is greater than or equal to −10° and less than or equal to 10°, and accordingly includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

In this specification, trigonal and rhombohedral crystal systems are included in a hexagonal crystal system.

### Embodiment 1

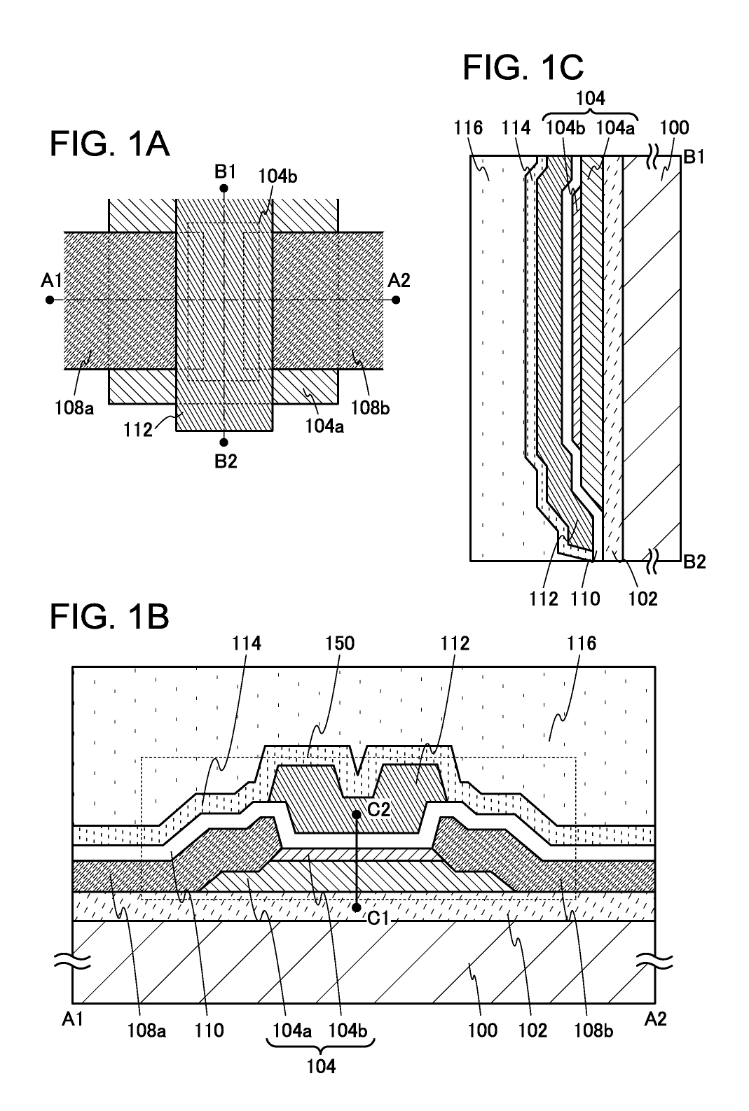

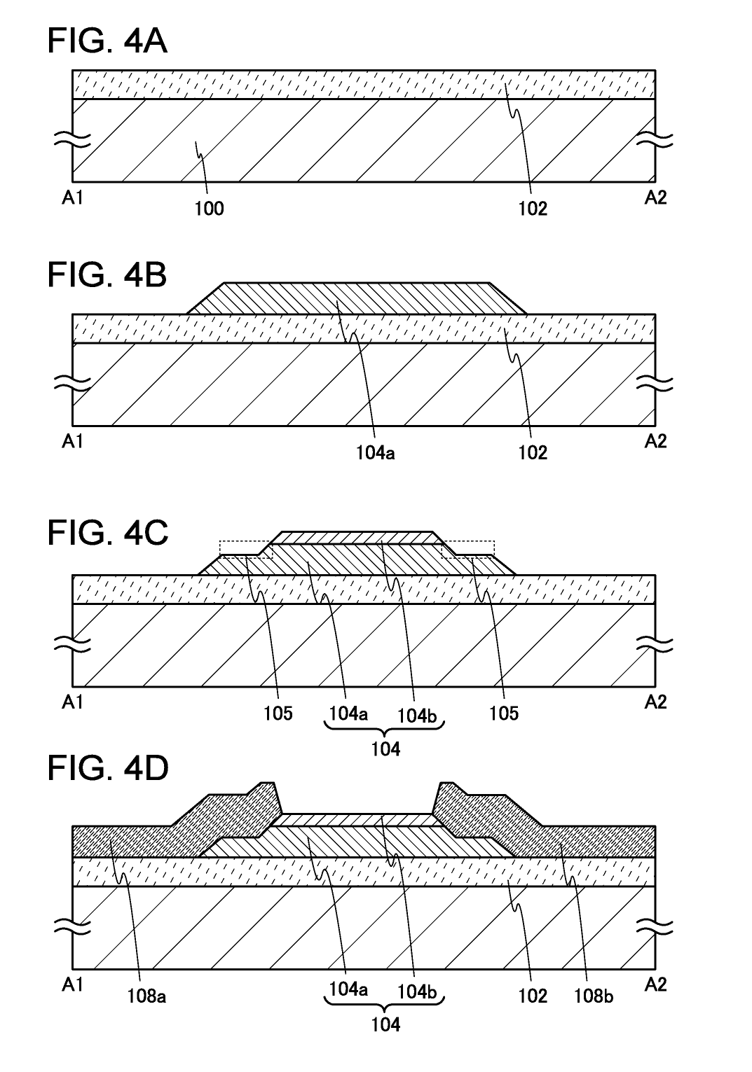

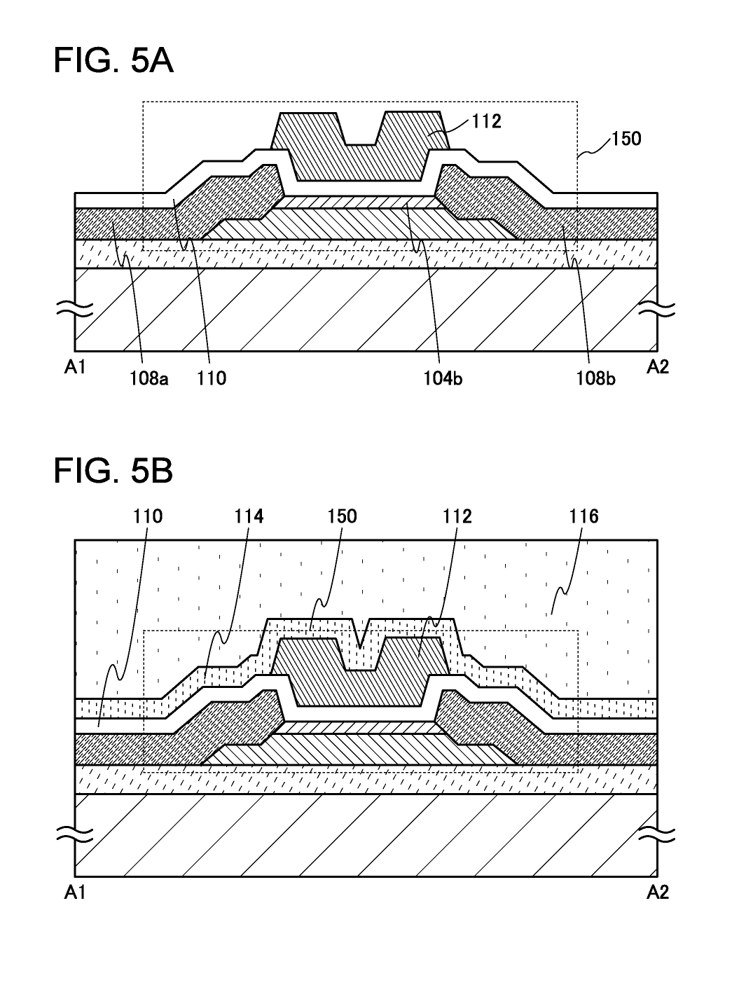

In this embodiment, a transistor and the like are described with reference to FIGS. 1A to 1C, FIGS. 2A and 2B, and FIG. 3 as an example of a semiconductor device, and an example of a method for manufacturing the transistor is described with reference to FIGS. 4A to 4D and FIGS. 5A and 5B.

### <Structure of Semiconductor Device>

FIGS. 1A to 1C illustrate the transistor described in this embodiment. FIG. 1A is a plan view of a transistor 150. FIG. 1B is a cross-sectional view taken along the dashed-dotted line A1-A2 in FIG. 1A. FIG. 1C is a cross-sectional view taken along the dashed-dotted line B1-B2 in FIG. 1A.

As illustrated in FIGS. 1A to 1C, the transistor 150 includes a first insulating layer 102 provided over a substrate 100, an oxide semiconductor layer 104 including a first oxide semiconductor film 104a provided over the first insulating layer 102 and a second oxide semiconductor film 104b, a source electrode 108a and a drain electrode 108b which are in contact with bottom surfaces and side surfaces of step portions of the first oxide semiconductor film 104a and whose edge portions are over the second oxide semiconductor film 104b, a gate insulating layer 110 over the second oxide semiconductor film 104b, the source electrode 108a, and the drain electrode 108b, and a gate electrode 112 which overlaps with the oxide semiconductor layer 104 with the gate insulating layer 110 provided therebetween. In addition, a second insulating layer 114 and a third insulating layer 116 are formed over the transistor 150.

Note that in the transistor 150, the first oxide semiconductor film 104a overlaps with the second oxide semiconductor film 104b and includes a first region having a first thickness and a second region overlapping with the source electrode 108a or the drain electrode 108b and having a second thickness. The second thickness is smaller than the first thickness. The step portion corresponds to a step between the first region and the second region.

One feature of the structure in this embodiment is that the oxide semiconductor layer 104 has a stacked-layer structure including at least the first oxide semiconductor film 104a whose main purpose is to function as a carrier path and the second oxide semiconductor film 104b which is provided in contact with and between the first oxide semiconductor film 104a and the gate insulating layer 110 and whose main purpose is to reduce interface state density; the first oxide semiconductor film 104a and the second oxide semiconductor film 104b contain the same metal element as their main component; and the second oxide semiconductor film 104b has electron affinity lower than electron affinity of the first oxide semiconductor film 104a by 0.1 eV or more.

In a top contact transistor in which a source electrode and a drain electrode are connected to a top surface of an oxide semiconductor layer, an interface state is generally generated at the interface between the oxide semiconductor layer and an insulating film (e.g., a gate insulating film) in contact with the oxide semiconductor layer, resulting in various adverse effects on electrical characteristics, such as decreases in ON/OFF ratio, field-effect mobility, and a subthreshold swing.

In contrast, since the transistor 150 illustrated in FIGS. 1A to 1C has the structure including the above feature, carriers selectively flow in the first oxide semiconductor film 104a which is close to the second oxide semiconductor film 104b in the oxide semiconductor layer 104. In addition, an interface state is decreased at the interface between the first oxide semiconductor film 104a and the second oxide semiconductor film 104b (i.e., an interface which is close to a channel formation region), as compared to the case where the oxide semiconductor layer 104 and the gate insulating layer 110 are in direct contact with each other, which makes it possible to reduce adverse effects on electrical characteristics, such as decreases in ON/OFF ratio, field-effect mobility, and a subthreshold swing.

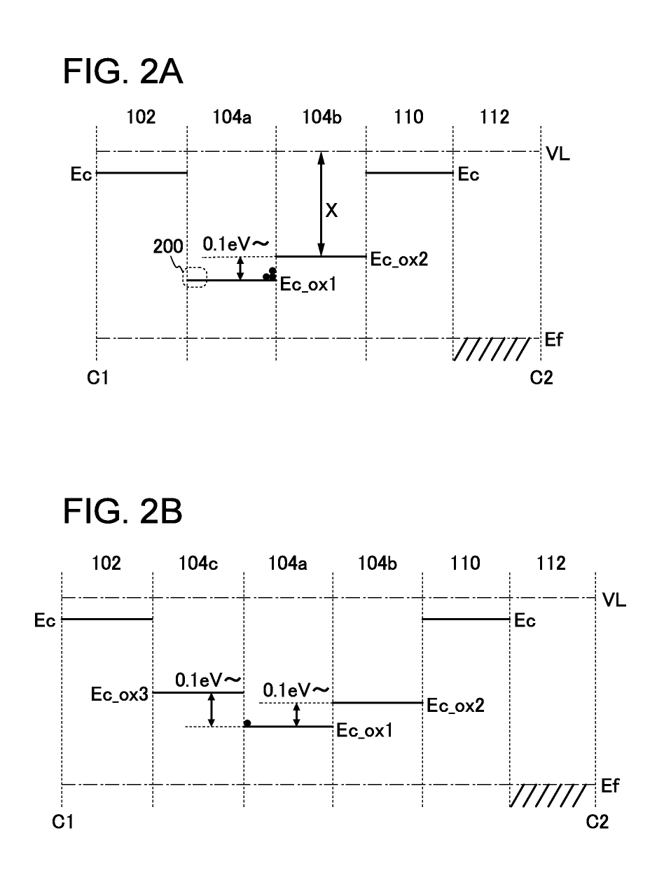

A concept of carrier conduction owing to formation of the second oxide semiconductor film 104b which is in contact with the first oxide semiconductor film 104a and has electron affinity lower than electron affinity of the first oxide semiconductor film 104a by 0.1 eV or more is briefly described with reference to FIGS. 2A and 2B.

FIG. 2A is a schematic view of the position relations between the bottoms of conduction bands (Ec) of the stacked films along the dashed-dotted line C1-C2 in FIG. 1C. Note that as for the gate electrode 112, the Fermi level is illustrated.

Electron affinity corresponds to energy difference between the vacuum level (VL) and the bottom of the conduction band. For example, a double-headed arrow X indicates electron affinity of the second oxide semiconductor film 104b.

Note that in FIG. 2A, the assumption is made that the first insulating layer 102 and the gate insulating layer 110 are each a single layer of silicon oxide. In addition, band bending (also referred to as band distortion) due to junction of the layers are not taken into account.

When a film with electron affinity lower than that of the first oxide semiconductor film 104a by 0.1 eV or more is used as the second oxide semiconductor film 104b, the bottom of the conduction band of the first oxide semiconductor film 104a (“Ec_ox1” in FIGS. 2A and 2B) is at a lower position than the bottom of the conduction band of the second oxide semiconductor film 104b (“Ec_ox2” in FIGS. 2A and 2B) by 0.1 eV or more as illustrated in FIG. 2A. This makes it possible for carriers to flow easily selectively in the first oxide semiconductor film 104a which is close to the interface between the first oxide semiconductor film 104a and the second oxide semiconductor film 104b (i.e., a position where black circles are illustrated in FIG. 2A (note that since FIG. 2A is a schematic view, the position is not accurate)).

As the second oxide semiconductor film 104b, a film with electron affinity lower than that of the first oxide semiconductor film 104a by 0.2 eV or more is preferably used, and a film with electron affinity lower than that of the first oxide semiconductor film 104a by 0.3 eV or more is more preferably used.

When a layer including a region where a channel is formed (here, the first oxide semiconductor film 104a) is directly in contact with the first insulating layer 102 as in the structure illustrated in FIGS. 1A to 1C, some carriers flow in also the first oxide semiconductor film 104a which is close to the first insulating layer 102 (which corresponds to a region 200 in FIG. 2A) and is on the back channel side in some cases. This phenomenon tends to be remarkable particularly in the case of the oxide semiconductor layer 104 with extremely small thickness, e.g., a thickness of 10 nm or less.

The flow of carriers is highly susceptible to the interface state at the interface between the first insulating layer 102 and the first oxide semiconductor film 104a. A method for reducing the influence is described below.

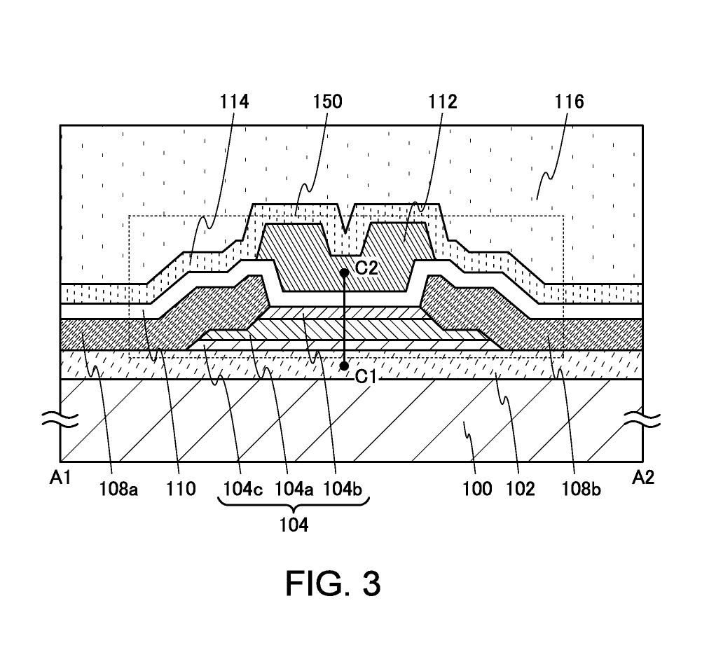

As the method for reducing the influence of the interface state, the following structure can be employed as illustrated in FIG. 3. A third oxide semiconductor film 104c is provided between the first oxide semiconductor film 104a and the first insulating layer 102 (also referred to as an insulating surface); a film with electron affinity lower than that of a film used as the first oxide semiconductor film 104a by 0.1 eV or more may be used as the third oxide semiconductor film 104c. Note that the third oxide semiconductor film 104c and the second oxide semiconductor film 104b may be formed of the same material.

In other words, as illustrated in FIG. 2B, the bottom of the conduction band of the first oxide semiconductor film 104a (Ec_ox1) is lower than the bottom of the conduction band of the second oxide semiconductor film 104b (Ec_ox2) and the bottom of the conduction band of the third oxide semiconductor film 104c (“Ec_ox3” in FIG. 2B) by 0.1 eV or more (preferably 0.2 eV or more, more preferably 0.3 eV or more); thus, the bottom of the conduction band of the first oxide semiconductor film 104a (Ec_ox2) forms a hollow part.

Consequently, carriers can easily selectively flow in the first oxide semiconductor film 104a which is close to the interface between the first oxide semiconductor film 104a and the third oxide semiconductor film 104c (i.e., a position where a black circle is illustrated in FIG. 2B (note that since FIG. 2B is a schematic view, the position is not accurate)).

Thus, the structure illustrated in FIG. 3 makes it possible to reduce influence of an interface state on the flow of carriers on both the front channel side and the back channel side.

Further, another feature of the structure in this embodiment is that the first oxide semiconductor film 104a includes a step portion overlapping with the source electrode 108a without overlapping with the second oxide semiconductor film 104b and a step portion overlapping with the drain electrode 108b without overlapping with the second oxide semiconductor film 104b, and the source electrode 108a and the drain electrode 108b are in contact with bottom surfaces and side surfaces of the step portions.

With the step portions, the surface area of the first oxide semiconductor film 104a which is in contact with the source electrode (or the drain electrode) can be increased, as compared to the case where the first oxide semiconductor film 104a does not include the step portions (e.g., the case where the first oxide semiconductor film 104a has tapered edge portions). Thus, carriers can be effectively injected into the first oxide semiconductor film 104a, which enables the transistor 150 to have good electrical characteristics such as ON/OFF ratio and field-effect mobility.

### <Method for Manufacturing Semiconductor Device>

Next, a method for manufacturing the transistor 150 and the like is described with reference to FIGS. 4A to 4D, FIGS. 5A and 5B, and FIGS. 6A to 6C.

First, the substrate 100 having an insulating surface is prepared, and the first insulating layer 102 is formed over the substrate 100 (see FIG. 4A).

There is no particular limitation on a substrate that can be used as the substrate 100 having an insulating surface as long as it has at least heat resistance to withstand heat treatment performed later. For example, a non-alkali glass substrate of barium borosilicate glass, aluminoborosilicate glass, or the like, a ceramic substrate, a quartz substrate, or a sapphire substrate can be used. As long as the substrate 100 has an insulating surface, a single crystal semiconductor substrate or a polycrystalline semiconductor substrate of silicon, silicon carbide, or the like; a compound semiconductor substrate of silicon germanium or the like; an SOI substrate; or the like can be used.

Note that the substrate 100 is preferably subjected to heat treatment at a temperature lower than the strain point of the substrate 100 in advance to be shrunk (thermal shrinkage). As a result, the degree of shrinkage due to substrate heating in the manufacturing process of the transistor 150 can be reduced, so that mask misalignment in a light exposure step or the like can be suppressed, for example. In addition, moisture and organic substances which are attached to the surface of the substrate 100 can be removed by the heat treatment.

The first insulating layer 102 has a function of preventing diffusion of impurities (e.g., metal elements such as aluminum, magnesium, strontium, and boron, a nitrogen atom, a hydrogen atom, and water) from the substrate 100 to the oxide semiconductor layer 104, and preventing adverse influence on the electrical characteristics of the transistor 150 (for example, preventing a normally-on state of a transistor (a shift of the threshold voltage in the negative direction), the occurrence of variation in threshold voltage, and a reduction in field-effect mobility).

The first insulating layer 102 can be formed by a physical vapor deposition (PVD) method such as a vacuum deposition method and a sputtering method or a chemical vapor deposition (CVD) method such as a plasma CVD method to have a single-layer structure or a stacked-layer structure of a silicon oxide film, a silicon oxynitride film, a silicon nitride film, a silicon nitride oxide film, an aluminum oxide film, an aluminum nitride film, an aluminum oxynitride film, an aluminum nitride oxide film, or the like.

Note that in this specification, an “oxynitride film” refers to a film that includes more oxygen than nitrogen, and a “nitride oxide film” refers to a film that includes more nitrogen than oxygen.

In view of improving productivity and preventing diffusion of the impurities, the first insulating layer 102 preferably has a thickness greater than or equal to 50 nm and less than or equal to 500 nm, but does not necessarily have a thickness in the above range.

In the case of using the oxide semiconductor layer 104 as a semiconductor layer, the first insulating layer 102 preferably includes an oxide insulating film capable of releasing oxygen, the amount of which is greater than or equal to 1×10¹⁹ atoms/cm³ by heat treatment.

When there is oxygen vacancy in the oxide semiconductor layer 104, the oxygen vacancy causes carriers to be generated, which might exert adverse effects on the characteristics of the semiconductor device (for example, a channel exists even when a gate voltage is not applied, so that a drain current flows in the transistor (i.e., a transistor becomes normally-on)). For this reason, the oxide insulating film capable of releasing oxygen is formed as the first insulating layer 102 and then, heat treatment is performed on the oxide insulating film; thus, oxygen can be supplied to the oxide semiconductor layer 104. The oxygen vacancy of the oxide semiconductor layer 104 can be reduced in such a manner, resulting in good electrical characteristics of the transistor 150 using the oxide semiconductor layer 104 as the semiconductor layer.

To release oxygen by heat treatment means that the amount of released oxygen molecules is greater than or equal to 1.0×10¹⁸ molecules/cm³, preferably greater than or equal to 3.0×10¹⁹ molecules/cm³, more preferably 1.0×10²⁰ molecules/cm³ in thermal desorption spectroscopy (TDS).

In particular, the first insulating layer 102 preferably contains oxygen in a proportion higher than that of oxygen in the stoichiometric composition in (a bulk of) the film. For example, in the case where silicon oxide is used as the first insulating layer 102, a film of silicon oxide represented by SiO_{2+α} (α>0) is preferably used. Note that it is acceptable as long as a region containing oxygen in a proportion higher than that of oxygen in the stoichiometric composition (hereinafter referred to as an “oxygen-excessive region”) exists in at least part of the first insulating layer 102.

In the case where the first insulating layer 102 has a function of supplying oxygen to the oxide semiconductor layer 104 through heat treatment, the first insulating layer 102 preferably has a stacked-layer structure including a film with low oxygen permeability (e.g., an aluminum oxide film, a silicon nitride film, or a silicon nitride oxide film) and a film with high oxygen supply capability (a film containing oxygen in a proportion higher than that of oxygen in the stoichiometric composition) so that oxygen released from the first insulating layer 102 is efficiently supplied to the oxide semiconductor layer 104, and the film with low oxygen permeability is preferably formed between an insulating surface (here, the surface of the substrate 100) and the film with high oxygen supply capability. Thus, oxygen released from the film with high oxygen supply capability by heat treatment hardly diffuses downward below the film with high oxygen supply capability (on the substrate 100 side) and is efficiently supplied to the oxide semiconductor layer 104.

Note that if there is another film between the film with low oxygen permeability and the film with high oxygen supply capability, the other film might take in oxygen released from the film with high oxygen supply capability; therefore, the film with low oxygen permeability and the film with high oxygen supply capability are preferably in direct contact with each other.

It is preferable that the first insulating layer 102 contains as few hydrogen atoms as possible. This is because hydrogen atoms contained in the oxide semiconductor layer 104 which is formed in later steps are bonded to an oxide semiconductor, so that part of the hydrogen causes carriers to be generated, resulting in a change of the threshold voltage of the transistor in the negative direction. For this reason, in view of reduction of hydrogen atoms in the first insulating layer 102, a physical vapor deposition method performed without using a gas containing hydrogen, such as a sputtering method, is preferably used to form the first insulating layer 102.

However, in view of reduction of in-plane variation, mixing of particles, and film formation takt time (cycle time), a CVD method needs to be used to form the first insulating layer 102 in some cases.

When the first insulating layer 102 is formed by the CVD method, a gas containing hydrogen, such as a silane (SiH₄) gas, is used as a film formation gas in some cases. In such a case, a large amount of hydrogen might be contained in the first insulating layer 102.

Therefore, after the first insulating layer 102 is formed by the CVD method, heat treatment for the purpose of removal of hydrogen atoms in a film (hereinafter heat treatment for the purpose of removal of hydrogen atom in the film is referred to as “dehydration treatment” or “dehydrogenation treatment” in the specification) is preferably performed on the first insulating layer 102.

The heat treatment is performed at a temperature higher than or equal to 250° C. and lower than or equal to 650° C., preferably higher than or equal to 300° C. and lower than or equal to 600° C. or lower than the strain point of the substrate. For example, the substrate may be introduced into an electric furnace, which is one kind of heat treatment apparatuses, and heat treatment may be performed on the first insulating layer 102 at 350° C. for one hour in a vacuum (reduced pressure) atmosphere.

The heat treatment apparatus is not limited to the electric furnace, and a device for heating a processing object by heat conduction or heat radiation from a heating element such as a resistance heating element may be alternatively used. For example, an RTA (rapid thermal annealing) apparatus such as a GRTA (gas rapid thermal annealing) apparatus, or an LRTA (lamp rapid thermal annealing) apparatus can be used. The LRTA apparatus is an apparatus for heating a processing object by radiation of light (an electromagnetic wave) emitted from a lamp such as a halogen lamp, a metal halide lamp, a xenon arc lamp, a carbon arc lamp, a high pressure sodium lamp, or a high pressure mercury lamp. The GRTA apparatus is an apparatus for performing heat treatment using a high-temperature gas. As the high temperature gas, an inert gas which does not react with a processing object by heat treatment, such as nitrogen or a rare gas like argon, is used. Note that in the case where the GRTA apparatus is used as the heat treatment apparatus, the substrate may be heated in an inert gas heated to high temperature of 650° C. to 700° C. because the heat treatment time is short.

The heat treatment may be performed in an atmosphere of nitrogen, oxygen, ultra-dry air (the water content is lower than or equal to 20 ppm, preferably less than or equal to 1 ppm, more preferably less than or equal to 10 ppb), or a rare gas (such as argon or helium). Note that it is preferable that water, hydrogen, and the like are not contained in the atmosphere of nitrogen, oxygen, ultra-dry air, a rare gas, or the like. It is also preferable that the purity of nitrogen, oxygen, or the rare gas which is introduced into the heat treatment apparatus is set to be 6N (99.9999%) or higher, preferably 7N (99.99999%) or higher (that is, the impurity concentration is 1 ppm or lower, preferably 0.1 ppm or lower).

In the case where the heat treatment is performed on the first insulating layer 102, there is a possibility that part of oxygen as well as hydrogen is removed from the first insulating layer 102. Therefore, treatment for adding oxygen to the first insulating layer 102 (hereinafter treatment for the purpose of adding oxygen to a film is referred to as “oxygen adding treatment” or “treatment for making oxygen-excess state” in this specification) is preferably performed after the heat treatment.

Note that oxygen added to the first insulating layer 102 by the oxygen adding treatment includes at least one of an oxygen radial, ozone, an oxygen atom, and an oxygen ion (including a molecular ion and a cluster ion). By performing the oxygen adding treatment on the first insulating layer 102 which has been subjected to the dehydration treatment or dehydrogenation treatment, oxygen can be contained in the first insulating layer 102, which makes it possible to compensate for the release of oxygen from the first insulating layer 102 due to the dehydration treatment or dehydrogenation treatment.

As the oxygen adding treatment performed on the first insulating layer 102, heat treatment may be performed in an oxygen atmosphere, for example. An ion implantation method, an ion doping method, a plasma immersion ion implantation method, plasma treatment, or the like can be used as the oxygen adding treatment. Note that as the ion implantation method, a gas cluster ion beam may be used.

As a gas for supplying oxygen, a gas containing at least 0 is used; for example, an O₂ gas, an N₂O gas, a CO₂ gas, a CO gas, or an NO₂ gas can be used. Note that a rare gas (e.g., an Ar gas) may be contained in the gas for supplying oxygen.

In the case where the oxygen adding treatment is performed by the ion implantation method, the dosage of the oxygen is preferably greater than or equal to 1×10¹³ ions/cm² and less than or equal to 5×10¹⁶ ions/cm². The depth at which oxygen is implanted may be adjusted as appropriate by implantation conditions.

One or both of the oxygen adding treatment and the dehydration treatment (or dehydrogenation treatment) may be performed plural times. For example, when first oxygen adding treatment, dehydration treatment (or dehydrogenation treatment) and second oxygen adding treatment are sequentially performed, i.e., oxygen adding treatment is performed twice, a larger amount of oxygen can be added to a crystal structure of the first insulating layer 102 through the second oxygen adding treatment because distortion is caused in the crystal structure by the first oxygen adding treatment.

Further, the heat treatment may be performed after the oxide semiconductor layer 104 is formed. The oxygen released from the first insulating layer 102 by the heat treatment performed after the formation of the oxide semiconductor layer 104 has not only an effect of compensating the oxygen vacancies in the oxide semiconductor layer 104 but also an effect of reducing the interface state density between the first insulating layer 102 and the oxide semiconductor layer 104. Thus, carrier trapping at the interface between the oxide semiconductor layer and the first insulating layer 102 can be suppressed, which enables the transistor to have high reliability.

Note that the dehydration treatment (or dehydrogenation treatment) is not necessarily performed when the first insulating layer 102 is formed in an environment with extremely low hydrogen content (e.g., when the first insulating layer 102 is formed with the use of a sputtering apparatus).

The first insulating layer 102 preferably has a high surface flatness in addition to the function of supplying oxygen by heat treatment.

This is because the first insulating layer 102 with a low flatness causes the oxide semiconductor layer 104 formed in the later steps to have a low flatness, so that the electrical characteristics of the transistor 150 become worse in some cases. For example, when the oxide semiconductor layer 104 has a low flatness, mobility might be lowered due to unevenness in a channel portion.

As treatment for increasing the surface flatness of the first insulating layer 102 (hereinafter treatment for increasing the surface flatness of a film is referred to as planarization treatment), for example, chemical mechanical polishing (CMP) treatment, a dry etching method, or the like can be used. Note that the CMP treatment may be performed only once or plural times.

The first insulating layer 102 may have an average surface roughness (Rₐ) of, specifically, 1 nm or less, preferably 0.3 nm or less, more preferably 0.1 nm or less. When the CMP treatment is performed plural times, first polishing is preferably performed with a high polishing rate followed by final polishing with a low polishing rate. A combination of polishing steps with different polishing rates increases the flatness of a surface over which an oxide semiconductor is formed.

Note that Rₐ is obtained by expanding, into three dimensions, arithmetic mean surface roughness that is defined by JIS B 0601: 2001 (ISO4287:1997) so as to be able to apply it to a curved surface. Rₐ can be expressed as an “average value of the absolute values of deviations from a reference surface to a designated surface” and is defined by Formula 1.

$$\begin{matrix}[ Formula 1 ] & \\ {R}_{a} = \frac{1}{{S}_{0}} {\int }_{y 1}^{y 2} {\int }_{x 1}^{x 2} \vert f ( x , y ) - {Z}_{0} \vert d x d y & ( 1 )\end{matrix}$$

Here, the designated surface is a surface which is a target of roughness measurement, and is a quadrilateral region which is specified by four points represented by the coordinates (x₁, y₁, f(x₁, y₁)), (x₁, y₂, f(x₁, y₂)), (x₂, y₁, f(x₂, y₁)), and (x₂, y₂, f(x₂, y₂)). Moreover, S₀ represents the area of a rectangle which is obtained by projecting the designated surface on the xy plane, and Z₀ represents the height of the reference surface (the average height of the designated surface). Ra can be measured using an atomic force microscope (AFM).

Next, the first oxide semiconductor film 104a is formed over the first insulating layer 102 (see FIG. 4B).

The first oxide semiconductor film 104a may be formed in the following manner, for example: an oxide semiconductor film is formed by a PVD method or a CVD method, a resist mask is formed over the film by a photolithography method or the like and then, the oxide semiconductor film is selectively removed by a dry etching method, a wet etching method, or the like.

As the oxide semiconductor, for example, any of the following can be used: indium oxide; tin oxide; zinc oxide, an In—Zn-based oxide, an In—Mg-based oxide, or an In—Ga-based oxide, an In—Ga—Zn-based oxide (also referred to as IGZO), an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, an In—Sn—Ga—Zn-based oxide, an In—Hf—Ga—Zn-based oxide, In—Al—Ga—Zn-based oxide, an In—Sn—Al—Zn-based oxide, an In—Sn—Hf—Zn-based oxide, and an In—Hf—Al—Zn-based oxide.

Note that here, for example, an “In—Ga—Zn-based oxide” means an oxide containing In, Ga, and Zn as its main components and there is no particular limitation on the ratio of In, Ga, and Zn. The In—Ga—Zn-based oxide may contain a metal element other than the In, Ga, and Zn.

Alternatively, a material represented by a chemical formula, InMO₃(ZnO)ₘ (m>0 is satisfied, and m is not an integer) may be used as the oxide semiconductor. Note that M represents one or more metal elements selected from Ga, Fe, Mn, and Co. Alternatively, as the oxide semiconductor, a material represented by a chemical formula, In₂SnO₅(ZnO)₇, (n>0 is satisfied, n is an integer) may be used.

Note that when a large amount of hydrogen is contained in the first oxide semiconductor film 104a, hydrogen is bonded to the oxide semiconductor, so that part of the hydrogen causes carriers to be generated, resulting in a change of the threshold voltage of the transistor in the negative direction. Therefore, the hydrogen concentration in the oxide semiconductor layer 104 is preferably lower than 5×10¹⁸ atoms/cm³, more preferably lower than or equal to 1×10¹⁸ atoms/cm³, still more preferably lower than or equal to 5×10¹⁷ atoms/cm³, further more preferably lower than or equal to 1×10¹⁶ atoms/cm³. Note that the concentration of hydrogen in the first oxide semiconductor film 104a is measured by secondary ion mass spectrometry (SIMS).

Accordingly, when the oxide semiconductor film is formed as the first oxide semiconductor film 104a, it is preferable that a gas used in the film formation does not contain impurities such as water, hydrogen, a hydroxyl group, or hydride.

For example, it is preferable to use a film formation gas having a purity greater than or equal to 6N, preferably greater than or equal to 7N (i.e., the impurity concentration in the gas is less than or equal to 1 ppm, preferably less than or equal to 0.1 ppm). It is also preferable to use a film formation gas with a dew point of lower than or equal to −80° C., preferably lower than or equal to −100° C.

To remove moisture (including water, water vapor, hydrogen, a hydroxyl group, or hydroxide) in a film formation chamber, an entrapment vacuum pump such as a cryopump, an ion pump, or a titanium sublimation pump is preferably used. The evacuation unit may be a turbo molecular pump provided with a cold trap. With the use of the cryopump, a hydrogen atom, a compound containing a hydrogen atom, such as water (H₂O) (preferably, also a compound containing a carbon atom), and the like can be evacuated; accordingly, the concentration of impurities such as hydrogen or moisture in an oxide semiconductor film formed in the film formation chamber evacuated with the cryopump can be reduced.

In addition, it is preferable that the first oxide semiconductor film 104a contain nitrogen as little as possible. This is because, similarly to the case where hydrogen is contained, when nitrogen is bonded to the oxide semiconductor, part of the nitrogen serves as a donor and causes generation of an electron which is a carrier. Thus, an oxide semiconductor film in which the peak of the amount of ammonia molecules released from the film is less than or equal to 5.0×10²¹ molecules/cm³, preferably less than or equal to 1.0×10²¹ molecules/cm³, more preferably less than or equal to 8.0×10²¹ molecules/cm³ is preferably used as the first oxide semiconductor film 104a. The peak of the amount of ammonia molecules released from the first oxide semiconductor film 104a is obtained by TDS measurement performed after the film is heated.

Moreover, the concentration of alkali metals or alkaline earth metals in the first oxide semiconductor film 104a is preferably lower than or equal to 1×10¹⁸ atoms/cm³, more preferably lower than or equal to 2×10¹⁶ atoms/cm³. This is because, as in the case where hydrogen or nitrogen is contained, when an alkali metal or an alkaline earth metal is bonded with an oxide semiconductor, carriers are generated in some cases, which causes an increase in off-state current of the transistor.

The first oxide semiconductor film 104a is a single crystal oxide semiconductor film, a polycrystalline oxide semiconductor film, a microcrystalline (nanocrystalline) oxide semiconductor film, an amorphous oxide semiconductor film, or the like. The oxide semiconductor layer 104 may be a c-axis aligned crystalline oxide semiconductor (CAAC-OS) film.

A structure of an oxide semiconductor film is described below.

An oxide semiconductor film is classified roughly into a single-crystal oxide semiconductor film and a non-single-crystal oxide semiconductor film. The non-single-crystal oxide semiconductor film includes any of an amorphous oxide semiconductor film, a microcrystalline oxide semiconductor film, a polycrystalline oxide semiconductor film, a c-axis aligned crystalline oxide semiconductor (CAAC-OS) film, and the like.

The amorphous oxide semiconductor film has disordered atomic arrangement and no crystalline component. A typical example thereof is an oxide semiconductor film in which no crystal part exists even in a microscopic region, and the whole of the film is amorphous.

The microcrystalline oxide semiconductor film includes a microcrystal (also referred to as nanocrystal) with a size greater than or equal to 1 nm and less than 10 nm, for example. Thus, the microcrystalline oxide semiconductor film has a higher degree of atomic order than the amorphous oxide semiconductor film. Hence, the density of defect states of the microcrystalline oxide semiconductor film is lower than that of the amorphous oxide semiconductor film.

The CAAC-OS film is one of oxide semiconductor films including a plurality of crystal parts, and most of the crystal parts each fit inside a cube whose one side is less than 100 nm. Thus, there is a case where a crystal part included in the CAAC-OS film fits inside a cube whose one side is less than 10 nm, less than 5 nm, or less than 3 nm. The density of defect states of the CAAC-OS film is lower than that of the microcrystalline oxide semiconductor film. The CAAC-OS film is described in detail below.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor film of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned with a direction parallel to a normal vector of a formation surface or a normal vector of a top surface. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is higher than that in the vicinity of the formation surface in some cases. Further, when an impurity is added to the CAAC-OS film, the crystallinity in a region to which the impurity is added is changed, and the degree of crystallinity in the CAAC-OS film varies depending on regions.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ do not appear at around 36°.

In a transistor using the CAAC-OS film, change in electric characteristics due to irradiation with visible light or ultraviolet light is small. Thus, the transistor has high reliability.

Note that the first oxide semiconductor film 104a may be a stacked film including two or more films of an amorphous oxide semiconductor film, a microcrystalline oxide semiconductor film, and a CAAC-OS film, for example.

As noted in the description of FIG. 3, a structure may be employed in which the third oxide semiconductor film 104c is provided between the first insulating layer 102 and the first oxide semiconductor film 104a. When such a structure is employed, a film having electron affinity lower than that of the first oxide semiconductor film 104a by 0.1 eV or more is used as the third oxide semiconductor film 104c, as noted in the description of FIG. 3. As for a method for forming the third oxide semiconductor film 104c, for example, description of the second oxide semiconductor film 104b made below can be used for reference.

Oxide semiconductor films with different electron affinities can be formed by changing the composition ratio of metal elements contained as main components in the material.

For example, in the case of an In—Ga—Zn—O film, electron affinities of three In—Ga—Zn—O films with different composition ratios of metal elements are derived from results of band gaps measured by an ellipsometry method and results of work functions measured by an ultraviolet photoelectron spectroscopy (UPS) method. The composition ratios of metal elements are In:Ga:Zn=1:1:1, In:Ga:Zn=3:1:2, and In:Ga:Zn=1:3:2. When In:Ga:Zn=1:1:1, the electron affinity is 4.75 eV to 4.85 eV; when In:Ga:Zn=3:1:2, 4.9 eV to 5.0 eV; and when In:Ga:Zn=1:3:2, 4.3 eV to 4.7 eV.

Thus, for example, the use of the In—Ga—Zn—O film in which the ratio of In to Ga and Zn is 3:1:2 as the first oxide semiconductor film 104a and the use of the In—Ga—Zn—O film in which the ratio of In to Ga and Zn is 1:1:1 or the In—Ga—Zn—O film in which the ratio of In to Ga and Zn is 1:3:2 as the third oxide semiconductor film 104c enable the third oxide semiconductor film 104c to have electron affinity lower than that of the first oxide semiconductor film 104a by 0.1 eV or more.

Note that it is needless to say that the composition ratio of the metal elements in the In—Ga—Zn—O film is not limited to the above ratios. The composition ratio of the metal elements is not particularly limited as long as a film with electron affinity lower than that of the first oxide semiconductor film 104a by 0.1 eV or more is used as the third oxide semiconductor film 104c.

In addition, there is no particular limitation on the composition ratio of metal elements in the materials of the oxide semiconductor film other than the In—Ga—Zn—O film as long as a film with electron affinity lower than that of the first oxide semiconductor film 104a by 0.1 eV or more is used as the third oxide semiconductor film 104c.

As described above, with the third oxide semiconductor film 104c, an influence of an interface state on carriers flowing on the back channel side of the transistor 150 can be reduced, which enables the transistor 150 to have good electrical characteristics.

Other than the reduction of the interface state density, there is an advantage in providing the third oxide semiconductor film 104c.

When the first oxide semiconductor film 104a is formed, silicon atoms diffuse from the first insulating layer 102 into the first oxide semiconductor film 104a in some cases. For example, when the oxide semiconductor film is formed by a sputtering method, metal elements contained in the oxide semiconductor film (e.g., In, Ga, and Zn) are collided with the first insulating layer 102 vigorously, so that the Si atoms contained in the first insulating layer 102 are released from the first insulating layer 102 and diffused into the first oxide semiconductor film 104a in some cases (which is also referred to as mixing or the like).

On the other hand, the structure in which the third oxide semiconductor film 104c is provided between the first insulating layer 102 and the first oxide semiconductor film 104a as described above prevents diffusion of impurities from the first insulating layer 102 into the first oxide semiconductor film 104a with the third oxide semiconductor film 104c and reduces deterioration of the electrical characteristics of the transistor 150 due to diffusion of impurities from the first insulating layer 102 side because carriers selectively flow in the first oxide semiconductor film 104a which is close to the third oxide semiconductor film 104c.

To suppress the diffusion of impurities from the first insulating layer 102 side by the third oxide semiconductor film 104c as described above, the third oxide semiconductor film 104c preferably has a thickness greater than or equal to 2 nm and less than or equal to 50 nm, preferably greater than or equal to 3 nm and less than or equal to 30 nm, more preferably greater than or equal to 5 nm and less than or equal to 20 nm.

Next, the second oxide semiconductor film 104b is provided over the first oxide semiconductor film 104a to form the oxide semiconductor layer 104 (see FIG. 4C).

The second oxide semiconductor film 104b may be formed in such a manner that a film containing a metal element, which is the same as the metal element contained in the first oxide semiconductor film 104a as its main component, as its main component is formed by a sputtering method, a PVD method, a CVD method, or the like in a manner similar to that of the first oxide semiconductor film 104a, a resist mask is formed over the film by a photolithography method or the like, and then the film is selectively removed by a dry etching method, a wet etching method, or the like.

In addition, step portions (which correspond to regions 105 in FIG. 4C) are formed in the first oxide semiconductor film 104a through the etching for forming the second oxide semiconductor film 104b.

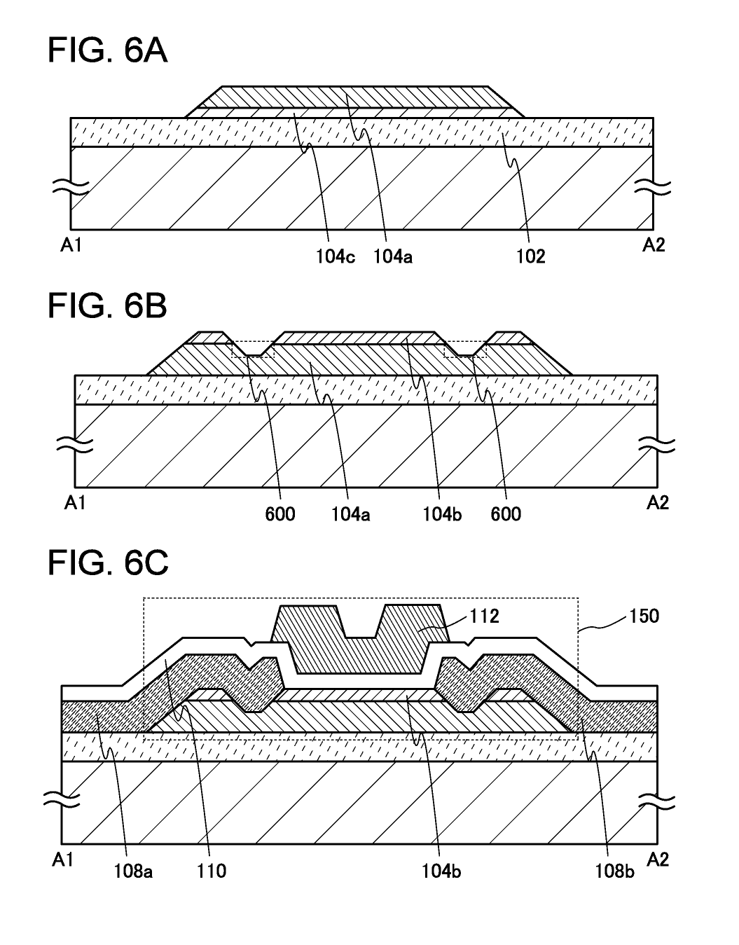

Although FIG. 4C illustrates a structure in which the step portions are formed in edge portions of the first oxide semiconductor film 104a which do not overlapped with the island-shaped second oxide semiconductor film 104b, a structure illustrated in FIG. 6B may be employed in which openings are formed in the second oxide semiconductor film 104b, and step portions (regions 600 in FIG. 6B) are formed in the first oxide semiconductor film 104a which are exposed in the openings.

For example, when the In—Ga—Zn—O film is used as the first oxide semiconductor film 104a, an oxide semiconductor film containing at least any one of In, Ga, and Zn as its main component, preferably an oxide semiconductor film containing In, Ga, and Zn as main components is used as the second oxide semiconductor film 104b.

Further, as the second oxide semiconductor film 104b, a film with electron affinity lower than that of the first oxide semiconductor film 104a by 0.1 eV or more is used.

The description of the first oxide semiconductor film 104a and the third oxide semiconductor film 104c can be used for reference; for example, the In—Ga—Zn—O film in which the ratio of In to Ga and Zn is 3:1:2 (electron affinity of which is 4.9 eV to 5.0 eV) is used as the first oxide semiconductor film 104a and the In—Ga—Zn—O film in which the ratio of In to Ga and Zn is 1:1:1 (electron affinity of which is 4.75 eV to 4.85 eV) or the In—Ga—Zn—O film in which the ratio of In to Ga and Zn is 1:3:2 (electron affinity of which is 4.3 eV to 4.7 eV) is used as the second oxide semiconductor film 104b, which enables the second oxide semiconductor film 104b to have electron affinity lower than that of the first oxide semiconductor film 104a by 0.1 eV or more.

As noted in the description of the first oxide semiconductor film 104a and the third oxide semiconductor film 104c, it is needless to say that the composition ratio of the metal elements in the In—Ga—Zn—O film is not limited to the above ratios. The composition ratio of the metal elements is not particularly limited as long as a film with electron affinity lower than that of the first oxide semiconductor film 104a by 0.1 eV or more is used as the second oxide semiconductor film 104b.

In addition, there is no particular limitation on the composition ratio of metal elements in the materials of the oxide semiconductor film other than the In—Ga—Zn—O film as long as a film with electron affinity lower than that of the first oxide semiconductor film 104a by 0.1 eV or more is used as the second oxide semiconductor film 104b.

Next, the source electrode 108a and the drain electrode 108b which are at least in contact with bottom surfaces and side surfaces of the step portions of the first oxide semiconductor film 104a and have step portions over the second oxide semiconductor film 104b are formed (see FIG. 4D).

As a material of the source electrode 108a and the drain electrode 108b, a material which can withstand the heat treatment performed in the manufacturing process of the transistor 150 is used. For example, a single layer or a stacked layer of a metal film containing an element selected from aluminum, chromium, copper, tantalum, titanium, molybdenum, and tungsten or a metal nitride film containing the element as its component (e.g., a titanium nitride film, a molybdenum nitride film, or a tungsten nitride film) may be formed by a PVD method.

To impart a low resistance property and high heat resistance to the source electrode 108a and the drain electrode 108b, the following structure may be employed, for example: a refractory metal film of titanium, molybdenum, tungsten, or the like or a metal nitride film thereof (e.g., a titanium nitride film, a molybdenum nitride film, or a tungsten nitride film) is stacked on a top surface and/or a bottom surface of a metal film of aluminum, copper, or the like which has low resistivity.

Note that when copper is used in part of the source electrode 108a and the drain electrode 108b, copper constituents might diffuse into the oxide semiconductor layer 104 due to the heat treatment performed in the formation of the transistor 150, in which case a barrier film is preferably formed on a surface which is in contact with the oxide semiconductor layer 104 to prevent diffusion of copper into the oxide semiconductor layer 104. As the barrier film, a tantalum nitride film, a stack of a tantalum nitride film and a tantalum film, a titanium nitride film, or a stack of a titanium nitride film and a titanium film can be used, for example.

In this embodiment, the first oxide semiconductor film 104a includes the step portions in the regions which do not overlap with the island-shaped second oxide semiconductor film 104b, and the source electrode 108a and the drain electrode 108b are formed in contact with the bottom surfaces and the side surfaces of the step portions. Alternatively, the structure illustrated in FIG. 6B may be employed in which the step portions (the regions 600 in FIG. 6B) are formed in the first oxide semiconductor film 104a exposed in the openings in the second oxide semiconductor film 104b, and the source electrode 108a and the drain electrode 108b are formed in contact with the bottom surfaces and the side surfaces of the step portions (see FIG. 6C).

Next, the gate insulating layer 110 is formed over the second oxide semiconductor film 104b, the source electrode 108a, and the drain electrode 108b; the gate electrode 112 overlapping with the oxide semiconductor layer 104 with the gate insulating layer 110 provided therebetween is formed (see FIG. 5A).

The gate insulating layer 110 can be formed by a physical vapor deposition (PVD) method such as a vacuum deposition method or a sputtering method, or a chemical vapor deposition (CVD) method such as a plasma CVD method to have a single-layer structure or a stacked-layer structure of an oxide film or an oxynitride film, such as a silicon oxide film, a silicon oxynitride film, an aluminum oxide film, an aluminum oxynitride film, a hafnium oxide film, a hafnium oxynitride film, a hafnium silicate film, or a hafnium silicate film containing nitrogen.

A film which is excellent at withstanding high voltage needs to be used for the gate insulating layer 110. For example, when a silicon nitride film, a silicon nitride oxide film, or the like is formed by a CVD method (e.g., a plasma CVD method), a gas containing hydrogen is used as a film formation gas in some cases.

If there are oxygen vacancies in the semiconductor layer when an oxide semiconductor material is used for the semiconductor layer, the oxygen vacancies cause carriers to be generated, which might exert adverse effects on the characteristics of the semiconductor device.

For this reason, with the use of a film containing a large amount of hydrogen atoms as the gate insulating layer 110, due to the heat treatment or the like performed in the manufacturing process of the transistor 150, hydrogen atoms released from the gate insulating layer 110 are bonded to oxygen in the oxide semiconductor layer 104 to form and release water, which might increase oxygen vacancies in the oxide semiconductor layer 104.

However, as described in this embodiment or the like, the second oxide semiconductor film 104b is provided between the first oxide semiconductor film 104a whose main purpose is to function as a carrier path and the gate insulating layer 110; thus, hydrogen released from the gate insulating layer 110 can be bonded to oxygen in the second oxide semiconductor film 104b; thus, an increase in the oxygen vacancies in the first oxide semiconductor film 104a serving as the carrier path can be prevented.

The gate electrode 112 may be formed in such a manner that a conductive film having a single-layer structure or a stacked-layer structure of a metal material such as molybdenum, titanium, tantalum, tungsten, aluminum, copper, neodymium, or scandium or an alloy material containing any of these metal materials as its main component is formed by a physical vapor deposition (PVD) method such as a vacuum deposition method or a sputtering method, a mask is formed over the conductive film by a photolithography method, a printing method, an inkjet method, or the like, and then part of the conductive film is selectively removed with the use of the mask.

Alternatively, a semiconductor film typified by a polycrystalline silicon film doped with an impurity element such as phosphorus, or a silicide film such as a nickel silicide film may be used as the gate electrode 112.

Further alternatively, a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added can be used as the material for the gate electrode 112. It is also possible that the gate electrode 112 has a stacked-layer structure of the above conductive material and the above metal material.

As one layer of the gate electrode 112 which is in contact with the gate insulating layer, a metal oxide containing nitrogen, specifically, an In—Ga—Zn—O film containing nitrogen, an In—Sn—O film containing nitrogen, an In—Ga—O film containing nitrogen, an In—Zn—O film containing nitrogen, an Sn—O film containing nitrogen, an In—O film containing nitrogen, or a metal nitride (InN, SnN, or the like) film can be used. These films each have a work function of 5 eV or higher, preferably 5.5 eV or higher, which enables the threshold voltage of the transistor to take a positive value when used as the gate electrode layer, so that what is called a normally-off switching element can be achieved.

There is no particular limitation on the thickness of the gate electrode 112. As the thickness decreases, the resistance of the gate electrode 112 increases, which exerts an influence upon the electrical characteristics of the transistor 150. As the thickness increases, the time needed to form the gate electrode 112 increases. Thus, the gate electrode 112 preferably has a thickness of greater than or equal to 50 nm and less than or equal to 500 nm.

Through the above steps, the transistor 150 is formed (see FIG. 5A).

Note that the second insulating layer 114 may be provided over the transistor 150 in order to prevent impurities such as moisture from entering the oxide semiconductor layer 104 from the outside (see FIG. 5B).

It is sufficient that the second insulating layer 114 is formed using a method and a material similar to those of the first insulating layer 102. As noted in the description of the first insulating layer 102, when the oxide semiconductor layer 104 is used as the semiconductor layer, oxygen the amount of which exceeds at least that of oxygen in the stoichiometric composition preferably exists in the second insulating layer 114 (a bulk) so that an oxide insulating film capable of releasing oxygen the amount of which is greater than or equal to 1×10¹⁹ atoms/cm³ is included by heat treatment. For example, when silicon oxide is used for the second insulating layer 114, a film of silicon oxide represented by SiO_{2+α} (α>0) is preferably used. Note that it is acceptable as long as a region containing oxygen in a proportion higher than that of oxygen in the stoichiometric composition (hereinafter also referred to as an “oxygen-excessive region”) exists in at least part of the second insulating layer 114.

The second insulating layer 114 preferably has a stacked-layer structure of a film with low oxygen permeability and a film with high oxygen supply capability so that oxygen released from the second insulating layer 114 is efficiently supplied to the oxide semiconductor layer 104 side. For example, the second insulating layer may have a stacked-layer structure of a film with low oxygen permeability, such as an aluminum oxide film, a silicon nitride film, or a silicon nitride oxide film (which is formed in contact with the gate electrode 112) and a silicon oxide film containing oxygen the amount of which exceeds that of oxygen in the stoichiometric composition as described above (which is formed in contact with the oxide semiconductor layer 104) (see FIG. 5B).

In the case where another semiconductor device or a leading wiring is formed over the transistor 150, the third insulating layer 116 for planarization may be formed over the second insulating layer 114 (see FIG. 5B).

The third insulating layer 116 may be formed in the following manner: a material having an insulating property is applied by a spin coating method, a printing method, a dispensing method, an inkjet method, or the like, and cure treatment (e.g., heat treatment or light irradiation treatment) is performed depending on the applied material, whereby a layer is formed; a resist mask in a desired pattern is formed over the layer with the use of a photolithography method, an inkjet method, or the like; and the layer is selectively removed by a dry etching method, a wet etching method, or the like.

As the material having an insulating property, an organic resin such as an acrylic resin, a polyimide resin, a polyamide resin, a polyamide-imide resin, or an epoxy resin, an inorganic material used for the first insulating layer 102, or an organic-inorganic hybrid material such as organic polysiloxane, can be used.

It is sufficient that the third insulating layer 116 has a thickness with which unevenness formed on the surface of the substrate when the second insulating layer 114 is formed can be planarized. The thickness is greater than or equal to 500 nm and less than or equal to 5000 nm, preferably greater than or equal to 500 nm and less than or equal to 3000 nm because productivity of the transistor 150 is reduced when the thickness of the third insulating layer 116 is too large.

Note that in this embodiment, the second insulating layer 114 and the third insulating layer 116 are formed over the transistor 150 in consideration of the barrier property against moisture and the planarity; however, practitioners may appropriately determine what kind of films are formed, and the structure of the semiconductor device is not limited to the above structure.

### Embodiment 2

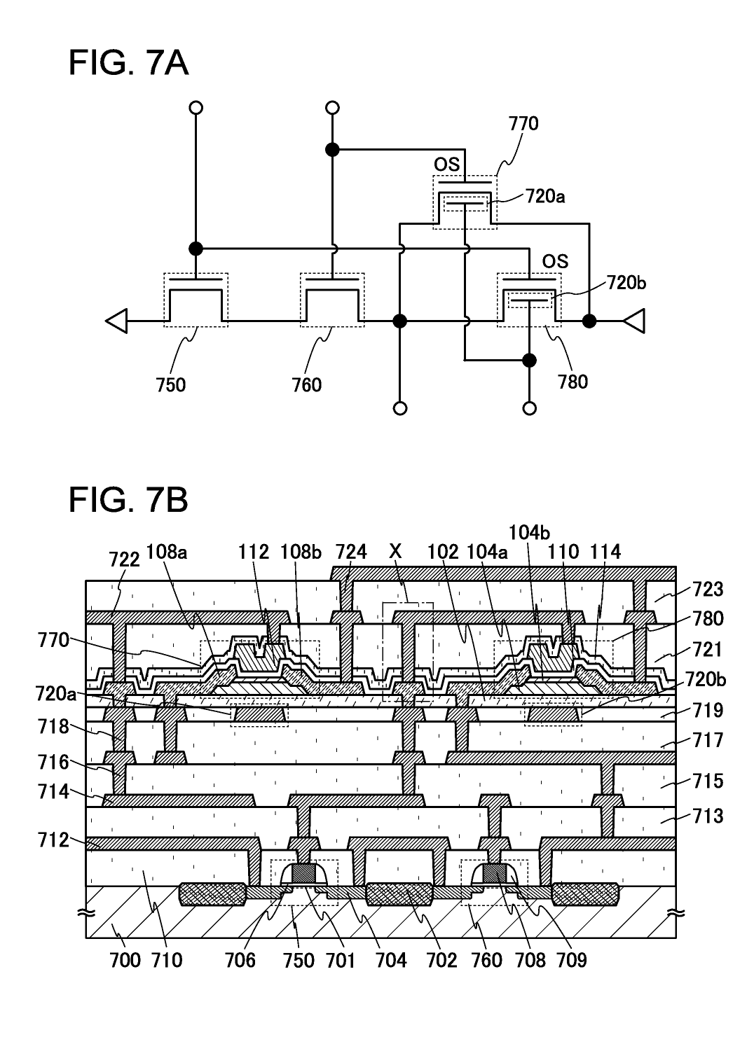

In this embodiment, as an example of a semiconductor device using the transistor described in Embodiment 1, a structure of a NAND circuit is described with reference to FIGS. 7A and 7B.

FIG. 7A is an example of a NAND circuit including the transistor which is described in Embodiment 1 and includes the semiconductor layer using the oxide semiconductor material. FIG. 7B is an example of a cross-sectional structure of the NAND circuit illustrated in FIG. 7A. In the NAND circuit, a first transistor 750 and a second transistor 760, which are p-channel transistors and in each of which single crystal silicon is used for an active layer, are provided over a single crystal silicon substrate 700, and a third transistor 770 and a fourth transistor 780, which are n-channel transistors and in each of which an oxide semiconductor material is used for an active layer like the transistor in Embodiment 1, are formed over the p-channel transistors.

The first transistor 750 and the second transistor 760 each include low-resistance regions 704 provided in the single crystal silicon substrate 700 and functioning as a source and a drain, a channel formation region 701 located in the single crystal silicon substrate 700 and between the low-resistance regions 704, a gate insulating film 706 over the channel formation region 701, and a gate electrode 708 provided over the channel formation region 701 with the gate insulating film 706 provided therebetween.

A separation layer 702 provided in the single crystal silicon substrate 700 separates the first transistor 750 and the second transistor 760. The low-resistance region 704 functioning as a drain of the first transistor 750 and the low-resistance region 704 functioning as a source of the second transistor 760 are electrically connected to each other through a first conductive film 712. The conductive film 712 is provided over a first interlayer film 710 covering the first transistor 750 and the second transistor 760. In addition, the gate electrode 708 is provided with sidewall insulating films 709 covering side surfaces of the gate electrode 708.

Materials and formation methods for the separation layer 702, the low-resistance regions 704, the gate insulating film 706, the gate electrode 708, the sidewall insulating films 709, the first interlayer film 710, and the first conductive film 712 are not particularly limited, and known techniques can be used.

The third transistor 770 and the fourth transistor 780 can each have a structure similar to that of the transistor 150 described in Embodiment 1. The third transistor 770 and the fourth transistor 780 each include the first oxide semiconductor film 104a provided over the first insulating layer 102, the second oxide semiconductor film 104b provided over the first oxide semiconductor film 104a, the source electrode 108a and the drain electrode 108b which are in contact with the bottom surfaces and the side surfaces of the step portions of the first oxide semiconductor film 104a and which includes the edge portions over the second oxide semiconductor film 104b, the gate insulating layer 110 provided over the second oxide semiconductor film 104b, the source electrode 108a, and the drain electrode 108b, and the gate electrode 112 provided over the first oxide semiconductor film 104a with the gate insulating layer 110 provided therebetween. As in Embodiment 1, the second insulating layer 114 and a fifth interlayer film 721 corresponding to the third insulating layer 116 are provided over the third transistor 770 and the fourth transistor 780.

In addition, between the first and second transistors 750 and 760 and the third and fourth transistors 770 and 780, a plurality of interlayer films (a second interlayer film 713, a third interlayer film 715, and a fourth interlayer film 717) or a plurality of conductive films (a second conductive film 714, a third conductive film 716, and a fourth conductive film 718) may be formed.

The second conductive film 714 provided over the second interlayer film 713 is electrically connected to the gate electrodes of the first transistor 750 and the second transistor 760 through the first conductive film 712, and lead wirings of the second conductive film 714 are formed over the second interlayer film 713. Further, the second conductive film 714 is also used as a plug (connection electrode) connecting an upper conductive film and a lower conductive film.

The third conductive film 716 provided over the third interlayer film 715 is electrically connected to a drain electrode of the second transistor 760 through the first conductive film 712 and the second conductive film 714, and lead wirings of the third conductive film 716 are formed over the third interlayer film 715. Further, the third conductive film 716 is also used as a plug (connection electrode) connecting an upper conductive film and a lower conductive film.

The fourth conductive film 718 which is provided over the fourth interlayer film 717 and embedded in an insulating film 719 is also used as a plug (connection electrode) connecting an upper conductive film and a lower conductive film. In addition, the fourth conductive film 718 is used to form a back gate electrode 720a of the third transistor 770 and a back gate electrode 720b of the fourth transistor 780.

Formation of the back gate electrode 720a and the back gate electrode 720b enables the threshold voltages of the third transistor 770 and the fourth transistor 780 to be controlled by application of voltage to the electrodes; thus, the third transistor 770 and the fourth transistor 780 can be prevented from being in a normally-on state.

Although the back gate electrode 720a of the third transistor 770 and the back gate electrode 720b of the fourth transistor 780 are electrically connected to each other in the NAND circuit illustrated in FIG. 7A, the back gate electrode 720a and the back gate electrode 720b may be electrically controlled independently.

The source electrode of the third transistor 770 and the source electrode of the fourth transistor 780 are electrically connected to the drain electrode of the second transistor 760 through the first conductive film 712, the second conductive film 714, the third conductive film 716, and the fourth conductive film 718. Note that although not connected in FIG. 7B, the source electrode of the third transistor 770 and the drain electrode of the second transistor 760 are electrically connected to each other in a portion which is not illustrated in the cross section.

Further, a plurality of interlayer films (e.g., the fifth interlayer film 721 and a sixth interlayer film 723) or a plurality of conductive films (e.g., a fifth conductive film 722 and a sixth conductive film 724) may be formed over the third transistor 770 and the fourth transistor 780.

The fifth conductive film 722 provided over the fifth interlayer film 721 (which corresponds to the third insulating layer 116 in Embodiment 1) is electrically connected to the gate electrode of the third transistor 770 and the gate electrode of the fourth transistor 780, and lead wirings of the fifth conductive film 722 are formed over the fifth interlayer film 721. In addition, the fifth conductive film 722 is electrically connected to the gate electrodes of the first transistor 750 and the second transistor 760 through the first conductive film 712, the second conductive film 714, the third conductive film 716, the fourth conductive film 718, and a conductive film formed of the same film as that of the source electrode (and the drain electrode) of the third transistor 770 (and the fourth transistor 780). Note that although not connected in FIG. 7B, the gate electrode of the third transistor 770 and the gate electrode of the second transistor 760 are electrically connected to each other in a portion which is not illustrated in the cross section. The fifth conductive film 722 is also used as a plug (connection electrode) connecting an upper conductive film and a lower conductive film.

The sixth conductive film 724 provided over the sixth interlayer film 723 is electrically connected to the drain electrode of the third transistor 770 and the drain electrode of the fourth transistor 780, and lead wirings of the sixth conductive film 724 are formed over the sixth interlayer film 723.

The first interlayer film 710 to the sixth interlayer film 723 can be formed using a method and a material similar to those of the third insulating layer 116 described in Embodiment 1.

The first conductive film 712 to the sixth conductive film 724 can be formed using a method and a material similar to those of the source electrode 108a and the drain electrode 108b described in Embodiment 1.

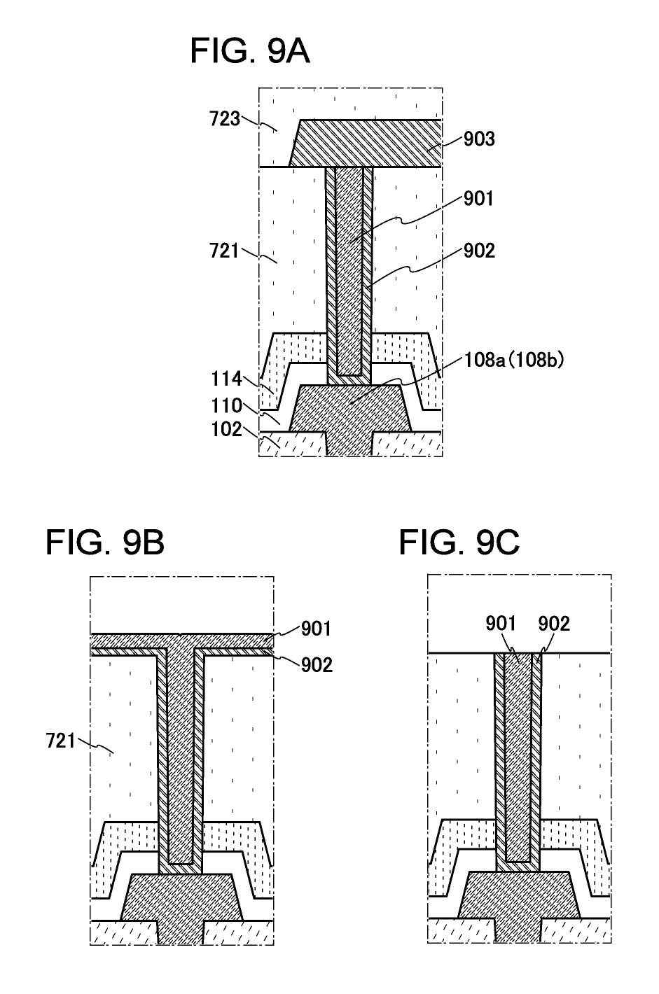

As illustrated in FIG. 9A, the conductive films may each have a structure in which a first metal film 901 is surrounded by a second metal film 902 and a third metal film 903 in a plug (connection electrode) portion.

When the plug (connection electrode) portion is made to have low resistance, a low resistance metal film of copper, a copper alloy, or the like is used as the first metal film 901, for example. Then, to prevent diffusion of copper from the first metal film 901, a metal film having a high capacity for preventing diffusion of copper is used as the second metal film 902 and the third metal film 903. As the metal film, a tantalum nitride film, a molybdenum nitride film, a tungsten nitride film, or the like can be used, for example.

The conductive films may each include a plug (connection electrode) portion having the structure in FIG. 9A in the following manner. First, the second metal film 902 and the first metal film 901 are formed in an opening provided in the fifth interlayer film 721 (see FIG. 9B). Removing treatment such as CMP treatment is performed until the fifth interlayer film 721 is exposed (see FIG. 9C). Then, the third metal film 903 is formed.

As described above, the use of a transistor having the structure described in Embodiment 1 as some of the transistors included in the NAND circuit enables the transistor to have excellent electrical characteristics such as ON/OFF ratio and field-effect mobility, resulting in an increase in the performance of the NAND circuit. Since the transistor described in Embodiment 1 has extremely small off-state current, the NAND circuit part of which includes the transistor can consume less power.

Although the description is given of the example of using the transistor 150 described in Embodiment 1 for the NAND circuit in this embodiment, the transistor 150 described in Embodiment 1 may be used as some of transistors included in a NOR circuit.

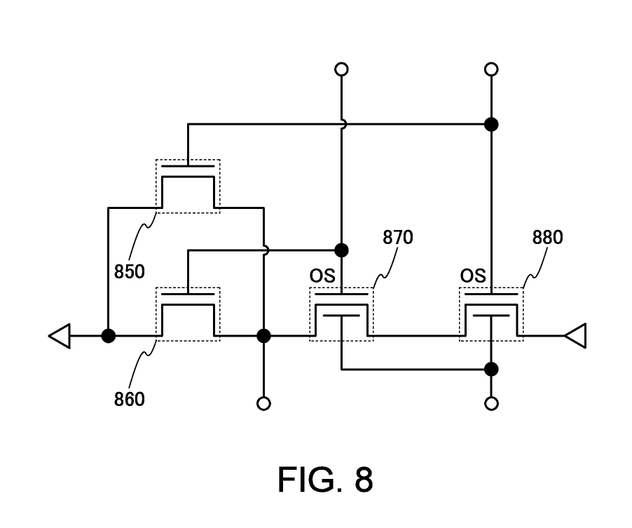

FIG. 8 is an example of a NOR circuit including the transistor which is described in Embodiment 1 and includes the semiconductor layer using the oxide semiconductor material. As in the NAND circuit, in the NOR circuit, a fifth transistor 850 and a sixth transistor 860, which are p-channel transistors and in each of which single crystal silicon is used for an active layer, are provided, and a seventh transistor 870 and an eighth transistor 880, which are n-channel transistors and in each of which an oxide semiconductor material is used for an active layer like the transistor in Embodiment 1, are formed over the p-channel transistors.

Description of a cross-sectional view of the NOR circuit is omitted here. Like the NAND circuit, the NOR circuit can be formed in such a manner that a plurality of interlayer films or conductive films is formed between the fifth transistor 850 and the sixth transistor 860 in each of which single crystal silicon is used for the active layer and the seventh transistor 870 and the eighth transistor 880 in each of which the oxide semiconductor material is used for the active layer, and lead wirings of the conductive films are formed; a plurality of interlayer films or conductive films is also formed over the seventh transistor 870 and the eighth transistor 880, and wirings of the conductive films are formed.

As described above, the use of a transistor having the structure described in Embodiment 1 as some of the transistors included in the NOR circuit enables the transistor to have excellent electrical characteristics such as ON/OFF ratio and field-effect mobility, resulting in an increase in the performance and a decrease in the power consumption of the NOR circuit like the NAND circuit.

The above is the description of the NAND circuit (and the NOR circuit) using the transistor described in Embodiment 1.

### Embodiment 3

In this embodiment, a configuration of a memory cell with nonvolatile properties, in which the transistor 150 described in Embodiment 1 is used for part of a component is described.

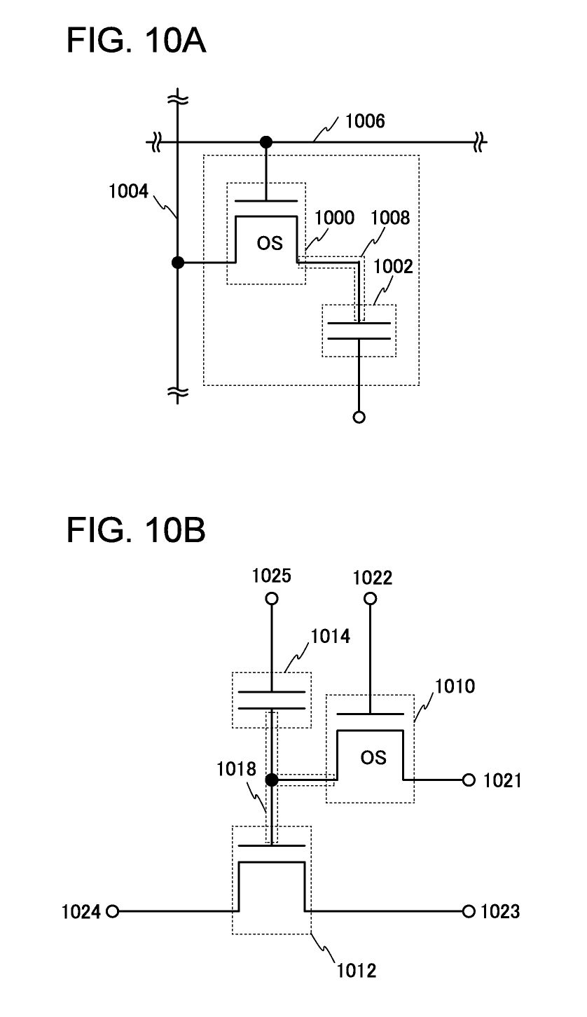

As the memory cell with nonvolatile properties, examples of configurations illustrated in FIGS. 10A and 10B can be given.

FIG. 10A is an example of a configuration of a memory cell with nonvolatile properties, and a transistor 1000 and a capacitor 1002 are connected in series. The configuration itself is generally used in a DRAM; however, the transistor 150 is used as the transistor 1000. One of a source and a drain of the transistor 1000 is connected to a bit line 1004, and a gate of the transistor 1000 is connected to a word line 1006. Further, one of electrodes of the capacitor 1002 is connected to the other of the source and the drain of the transistor 1000, and the other electrode of the capacitor 1002 is connected to a fixed potential (e.g., a ground potential).

As described in Embodiment 1, the transistor including the semiconductor layer using the oxide semiconductor material can realize an extremely small off-state current. The transistor including the semiconductor layer using the oxide semiconductor material is used for the transistor 1000 connected to the capacitor 1002 as illustrated in FIG. 10A (such a transistor can also be referred to as a transistor which controls input/output of a signal to/from the capacitor 1002). First, the transistor 1000 is turned on in accordance with a signal from the word line 1006, and then the transistor 1000 is turned off in accordance with the signal from the word line 1006 while a signal from the bit line 1004 is supplied to the one of the electrodes of the capacitor 1002. In this manner, a signal input through the bit line 1004 can be stored in a region (which corresponds to a node 1008 in FIG. 10A) between the other of the source and the drain of the transistor 1000 and the one of the electrodes of the capacitor 1002 for a long time even when power is not supplied to the memory cell (writing).

Then, the transistor 1000 is turned on in accordance with the signal from the word line 1006, so that data stored in the node 1008 can be read out (reading). Note that in the case where the signal read from the memory cell is small, a signal amplifier such as a sense amplifier may be provided in the output path as necessary.

FIG. 10B is an example of a configuration of a memory cell with nonvolatile properties. The memory cell includes a first transistor 1010, a second transistor 1012, and a capacitor 1014. In the memory cell, one of a source and a drain of the first transistor 1010 is connected to a first line 1021 (1st line), a gate of the first transistor 1010 is connected to a second line 1022 (2nd line), one of a source and a drain of the second transistor 1012 is connected to a third line 1023 (3rd line), and the other of the source and the drain of the second transistor 1012 is connected to a fourth line 1024 (4th line). Further, one of electrodes of the capacitor 1014 is connected to the other of the source and the drain of the first transistor 1010 and a gate of the second transistor 1012, and the other of the electrodes of the capacitor 1014 is connected to a fifth line 1025 (5th line).

As illustrated in FIG. 10B, the first transistor 1010 is the transistor including the semiconductor layer using the oxide semiconductor material; therefore, the first transistor 1010 is turned on by a signal from the second line 1022, and the first transistor 1010 is turned off by the signal from the second line 1022 while a signal from the first line 1021 is supplied to the gate of the second transistor 1012 and the one of the electrodes of the capacitor 1014. In this manner, a signal input through the first line 1021 can be stored in a region (which corresponds to a node 1018 in FIG. 10B) among the other of the source and the drain of the first transistor 1010, the gate of the second transistor 1012, and one of the electrodes of the capacitor 1014 for a long time even when power is not supplied to the memory cell (writing).

For data reading, an appropriate potential (a reading potential) is applied to the fifth line 1025 while a predetermined potential (a constant potential) is supplied to the third line 1023 first, whereby the potential of the fourth line 1024 varies depending on the amount of charge stored in the node 1018. This is because in general, when the second transistor 1012 is an n-channel transistor, an apparent threshold voltage Vₜₕ_{_{—}}_{H} in the case where a high-level charge is given to the gate of the second transistor 1012 is lower than an apparent threshold voltage Vₜₕ_{_{—}}_{L} in the case where a low-level charge is given to the gate of the second transistor 1012. Here, the apparent threshold voltage refers to the potential of the fifth line 1025 needed to turn on the second transistor 1012. Thus, the potential of the fifth line 1025 is set to a potential V₀ which is between Vₜₕ_{_{—}}_{H} and Vₜₕ_{_{—}}_{L}, whereby charge supplied to the gate of the second transistor 1012 can be determined. For example, in the case where a high-level charge is given in writing, when the potential of the fifth line 1025 is set to V₀ (>Vₜₕ_{_{—}}_{H}), the second transistor 1012 is turned on. In the case where a low-level charge is given in writing, even when the potential of the fifth line 1025 is set to V₀ (<Vₜₕ_{_{—}}_{L}), the second transistor 1012 remains in an off state. Therefore, the stored data can be read out by checking the potential of the fourth line 1024.

Note that in the case where memory cells are arrayed to be used, only data of desired memory cells needs to be read. In the case where such reading is not performed, a potential at which the second transistor 1012 is turned off, that is, a potential smaller than Vₜₕ_{_{—}}_{H} may be given to the fifth line 1025 regardless of the state of the gate of the second transistor 1012. Alternatively, a potential at which the second transistor 1012 is turned on, that is, a potential higher than Vₜₕ_{_{—}}_{L} may be given to the fifth line 1025 regardless of the state of the gate of the second transistor 1012.

As described above, since the transistor has an extremely small off-state current, the use of the transistor described in Embodiment 1 in part of the memory cell with nonvolatile properties enables the memory cell to store data for a long time without performing treatment which consumes power, such as refresh operation. In addition, since the transistor described in Embodiment 1 has excellent electrical characteristics such as ON/OFF ratio and field-effect mobility, the memory cell can have high performance.

An apparatus and a method similar to those for forming a thin film transistor using silicon or the like can be used for the transistor 1000 and the first transistor 1010 in each of which the oxide semiconductor material is used for the semiconductor layer, resulting in reduction of the burden of new capital investment or a study of the manufacturing method. Note that as described in Embodiment 2, the transistor in which the oxide semiconductor material is used for the semiconductor layer can be stacked over a transistor in which a material other than the oxide semiconductor material is used for the semiconductor layer (e.g., a transistor in which single crystal silicon is used for a semiconductor layer).

### Embodiment 4

In this embodiment, as an example of a semiconductor device, description is given of a central processing unit (CPU) at least part of which includes the transistor 150 described in Embodiment 1, the NAND circuit and the NOR circuit described in Embodiment 2, the memory cell with nonvolatile properties described in Embodiment 3, and the like.

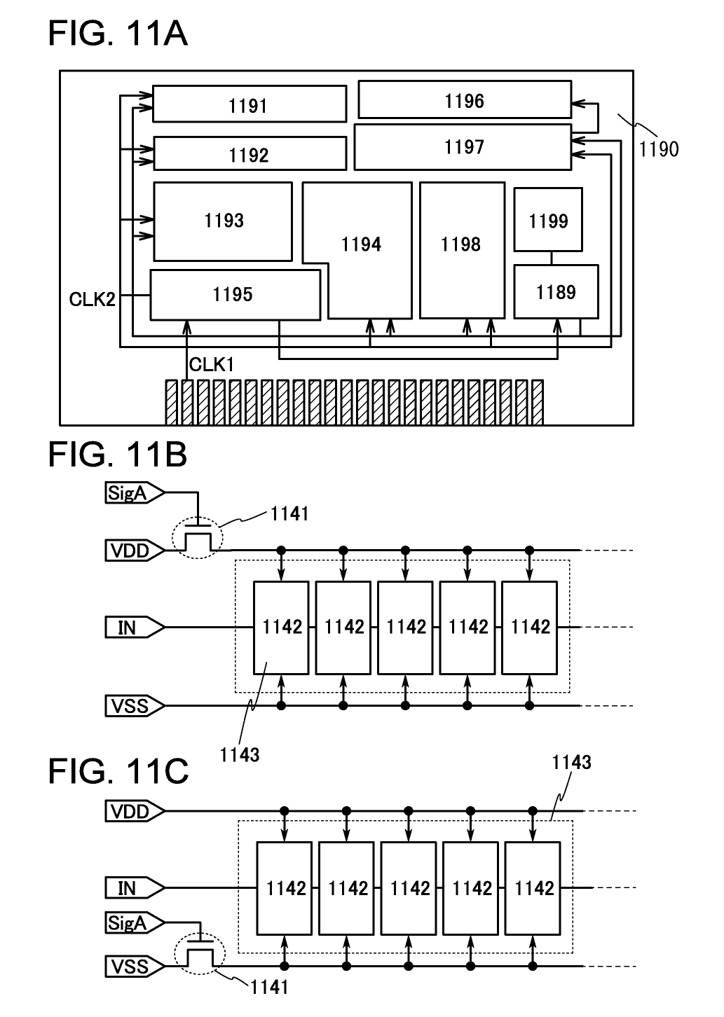

FIG. 11A is a block diagram illustrating a specific configuration of a CPU. The CPU illustrated in FIG. 11A includes an arithmetic logic unit (ALU) 1191, an ALU controller 1192, an instruction decoder 1193, an interrupt controller 1194, a timing controller 1195, a register 1196, a register controller 1197, a bus interface (Bus I/F) 1198, a rewritable ROM 1199, and an ROM interface (ROM I/F) 1189 over a substrate 1190. A semiconductor substrate, an SOI substrate, a glass substrate, or the like is used as the substrate 1190. The ROM 1199 and the ROM interface 1189 may each be provided over a separate chip. Obviously, the CPU illustrated in FIG. 11A is only an example in which the configuration is simplified, and an actual CPU may have various configurations depending on the application.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the internal clock signal CLK2 to the above circuits.

A plurality of logic circuits is provided in the components included in the CPU. When a NAND circuit or a NOR circuit is provided in each of the logic circuits, the NAND circuit or the NOR circuit described in Embodiment 2 can be used. Thus, the NAND circuit or the NOR circuit can have good electrical characteristics and low power consumption, which contributes to high performance and low power consumption of the CPU.

In the CPU illustrated in FIG. 11A, a memory cell is provided in the register 1196. As the memory cell in the register 1196, the memory cell described in Embodiment 3 can be used, for example. This allows the memory cell in the register 1196 to store data for a long time without performing treatment which consumes power, such as refresh operation, and to write or read data at high speed, which contributes to high performance and low power consumption of the CPU.

In the CPU illustrated in FIG. 11A, the register controller 1197 selects operation of holding data in the register 1196 in accordance with an instruction from the ALU 1191. That is, the register controller 1197 selects whether data is held by a flip-flop or by a capacitor in the memory cell included in the register 1196. When data holding by the flip-flop is selected, a power supply voltage is supplied to the memory cell in the register 1196. When data holding by the capacitor is selected, the data is rewritten in the capacitor, and supply of power supply voltage to the memory cell in the register 1196 can be stopped.

The power supply can be stopped by providing a switching element between a memory cell group and a node to which a power supply potential VDD or a power supply potential VSS is supplied, as illustrated in FIG. 11B or FIG. 11C. Circuits illustrated in FIGS. 11B and 11C are described below.

In each of FIGS. 11B and 11C, the transistor 150 described in Embodiment 1 can be used as the switching element controlling supply of a power supply potential to the memory cell, for example. The transistor has excellent electrical characteristics, such as ON/OFF ratio and field-effect mobility, and an extremely small off-state current which enables accurate high-speed operation of the switching element and reduction in power consumption of the switching element in a non-operation state, resulting in a contribution to high performance and low power consumption of the CPU.

The memory device illustrated in FIG. 11B includes a switching element 1141 and a memory cell group 1143 including a plurality of memory cells 1142. Specifically, as each of the memory cells 1142, the memory cell described in Embodiment 3 can be used. Each of the memory cells 1142 included in the memory cell group 1143 is supplied with the high-level power supply potential VDD through the switching element 1141. Further, each of the memory cells 1142 included in the memory cell group 1143 is supplied with a potential of a signal IN and the low-level power supply potential VSS.

In FIG. 11B, the transistor described in Embodiment 1 is used as the switching element 1141, and the switching of the transistor is controlled by a signal SigA supplied to a gate electrode layer thereof.

Note that FIG. 11B illustrates the configuration in which the switching element 1141 includes only one transistor; however, without particular limitation thereon, the switching element 1141 may include a plurality of transistors. In the case where the switching element 1141 includes a plurality of transistors which serves as switching elements, the plurality of transistors may be connected to each other in parallel, in series, or in combination of parallel connection and series connection.

Although the switching element 1141 controls the supply of the high-level power supply potential VDD to each of the memory cells 1142 included in the memory cell group 1143 in FIG. 11B, the switching element 1141 may control the supply of the low-level power supply potential VSS.

In FIG. 11C, an example of a memory device in which each of the memory cells 1142 included in the memory cell group 1143 is supplied with the low-level power supply potential VSS through the switching element 1141 is illustrated. The supply of the low-level power supply potential VSS to each of the memory cells 1142 included in the memory cell group 1143 can be controlled by the switching element 1141.

When a switching element is provided between a memory cell group and a node to which the power supply potential VDD or the power supply potential VSS is supplied, data can be held even in the case where an operation of a CPU is temporarily stopped and the supply of the power supply voltage is stopped; accordingly, power consumption can be reduced. Specifically, for example, while a user of a personal computer does not input data to an input device such as a keyboard, the operation of the CPU can be stopped, so that the power consumption can be reduced.

Although the CPU is given as an example, the transistor can also be applied to an LSI such as a digital signal processor (DSP), a custom LSI, or a field programmable gate array (FPGA).

The structures and methods described in this embodiment can be combined as appropriate with any of the structures and methods described in the other embodiments.

### Embodiment 5

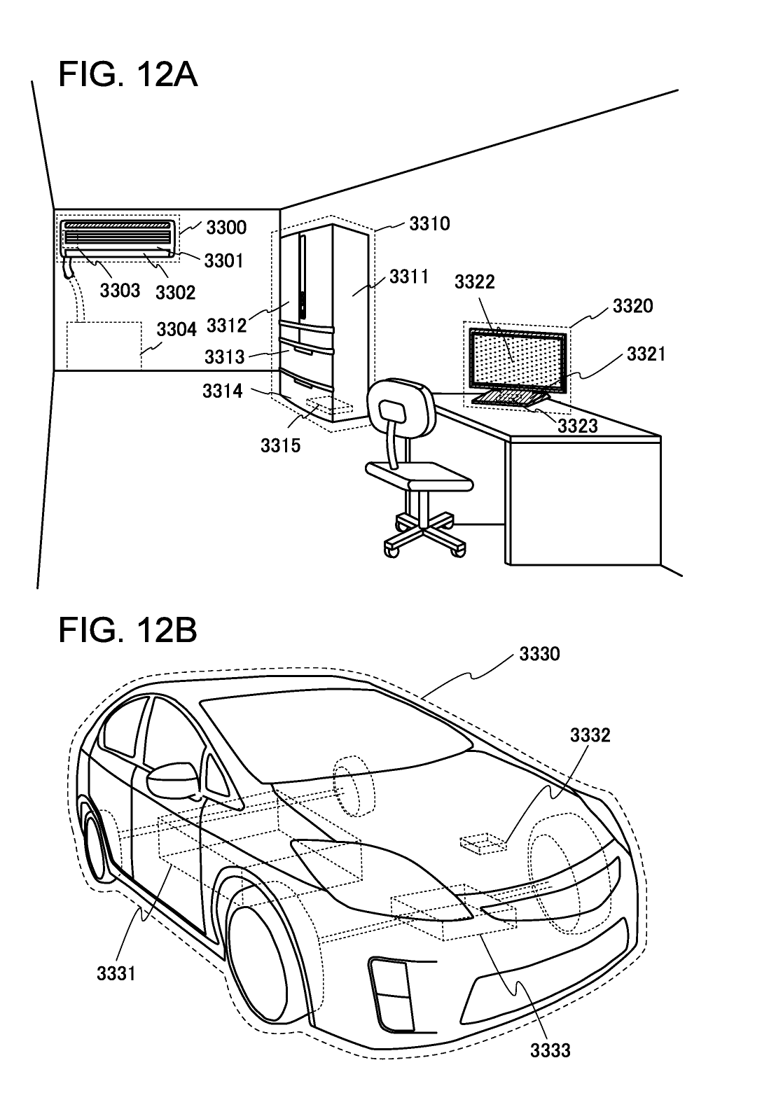

Any of the semiconductor devices disclosed in this specification can be applied to a variety of electronic appliances (including game machines). Examples of the electronic appliances include display devices of televisions, monitors, and the like, lighting devices, desktop personal computers and notebook personal computers, word processors, image reproduction devices which reproduce still images or moving images stored in recording media such as digital versatile discs (DVDs), portable compact disc (CD) players, radio receivers, tape recorders, headphone stereos, stereos, cordless phone handsets, transceivers, mobile phones, car phones, portable game machines, calculators, portable information terminals, electronic notebooks, e-book readers, electronic translators, audio input devices, cameras such as still cameras and video cameras, electric shavers, high-frequency heating appliances such as microwave ovens, electric rice cookers, electric washing machines, electric vacuum cleaners, air-conditioning systems such as air conditioners, dishwashers, dish dryers, clothes dryers, futon dryers, electric refrigerators, electric freezers, electric refrigerator-freezers, freezers for preserving DNA, smoke detectors, radiation counters, and medical equipment such as dialyzers. Further, the examples include industrial equipment such as guide lights, traffic lights, belt conveyors, elevators, escalators, industrial robots, and power storage systems. In addition, moving objects driven by oil engines or motors using power from non-aqueous secondary batteries are also included in the category of electronic devices. Examples of the moving objects include electric vehicles (EV), hybrid electric vehicles (HEV) which include both an internal-combustion engine and a motor, plug-in hybrid electric vehicles (PHEV), tracked vehicles in which caterpillar tracks are substituted for wheels of these vehicles, motorized bicycles including motor-assisted bicycles, motorcycles, electric wheelchairs, golf carts, boats or ships, submarines, helicopters, aircrafts, rockets, artificial satellites, space probes, planetary probes, spacecrafts, and the like. Specific examples of these electronic appliances are shown in FIGS. 12A and 12B.

In FIG. 12A, an air conditioner which includes an indoor unit 3300 and an outdoor unit 3304 is an example of an electronic device which is provided with the semiconductor device described in any of the above embodiment. Specifically, the indoor unit 3300 includes a housing 3301, an air outlet 3302, a control device 3303, and the like. Although the control device 3303 is provided in the indoor unit 3300 in FIG. 12A, the control device 3303 may be provided in the outdoor unit 3304. Alternatively, the control device 3303 may be provided in both the indoor unit 3300 and the outdoor unit 3304.

The control device 3303 including at least any one of the transistor described in Embodiment 1, a logic circuit including the NAND circuit or the NOR circuit described in Embodiment 2, the memory cell with nonvolatile properties described in Embodiment 3, and the CPU described in Embodiment 4 enables an increase in the performance and a decrease in the power consumption of the air conditioner.

In FIG. 12A, an electric refrigerator-freezer 3310 is an example of an electronic device which is provided with the semiconductor device described in any of the above embodiments. Specifically, the electric refrigerator-freezer 3310 includes a housing 3311, a door for a refrigerator 3312, a door for a freezer 3313, a door for a vegetable drawer 3314, a control device 3315 provided in the housing 3311, and the like.

The control device 3315 including at least any one of the transistor described in Embodiment 1, a logic circuit including the NAND circuit or the NOR circuit described in Embodiment 2, the memory cell with nonvolatile properties described in Embodiment 3, and the CPU described in Embodiment 4 enables an increase in the performance and a decrease in the power consumption of the electric refrigerator-freezer 3310.

In FIG. 12A, an image display device 3320 is an example of an electronic device which is provided with the semiconductor device described in any one of the above embodiments. Specifically, the image display device 3320 includes a housing 3321, a display portion 3322, a control device 3323 provided in the housing 3321, and the like.

The control device 3323 including at least any one of the transistor described in Embodiment 1, a logic circuit including the NAND circuit or the NOR circuit described in Embodiment 2, the memory cell with nonvolatile properties described in Embodiment 3, and the CPU described in Embodiment 4 enables an increase in the performance and a decrease in the power consumption of the image display device 3320.

FIG. 12B illustrates an example of an electric vehicle which is an example of an electronic device. An electric vehicle 3330 is equipped with a secondary battery 3331. The output of power of the secondary battery 3331 is adjusted by a control device 3332, and the power is supplied to a driving device 3333. The control device 3332 includes ROM (not illustrated), RAM (not illustrated), a CPU (not illustrated), and the like.

The electric components such as the ROM, the RAM, and the CPU which are included in the control device 3332 and each of which include at least any one of the transistor described in Embodiment 1, a logic circuit including the NAND circuit or the NOR circuit described in Embodiment 2, the memory cell with nonvolatile properties described in Embodiment 3, and the CPU described in Embodiment 4 enable an increase in the performance and a decrease in the power consumption of the electric vehicle 3330, which contributes to high performance of the electric vehicle 3330.

This embodiment can be combined with any of the other embodiments as appropriate.

This application is based on Japanese Patent Application serial No. 2012-166568 filed with Japan Patent Office on Jul. 27, 2012, the entire contents of which are hereby incorporated by reference.

What is claimed is:

1. A semiconductor device comprising:
a first oxide semiconductor layer over a substrate;
a second oxide semiconductor layer over and in contact the first oxide semiconductor layer;
a source electrode and a drain electrode over the second oxide semiconductor layer;
a gate insulating layer over the second oxide semiconductor layer; and
a gate electrode over the gate insulating layer,
wherein the first oxide semiconductor layer has a step portion, the step portion being thinner than a portion other than the step portion, and
wherein a surface of the step portion is in contact with the source electrode and the drain electrode.

2. The semiconductor device according to claim 1, further comprising a first oxide insulating layer between the substrate and the first oxide semiconductor layer,
wherein the gate insulating layer comprises a second oxide insulating layer.

3. The semiconductor device according to claim 1,
wherein a constituent element of each of the first oxide semiconductor layer and the second oxide semiconductor layer is the same.

4. The semiconductor device according to claim 1,
wherein a side surface of the second oxide semiconductor layer is in contact with the source electrode and the drain electrode.

5. The semiconductor device according to claim 1,
wherein the step portion is located at an edge of the first oxide semiconductor layer.

6. An electronic device comprising the semiconductor device according to claim 1.

7. A semiconductor device comprising:
a first oxide semiconductor layer over a substrate;
a second oxide semiconductor layer over and in contact the first oxide semiconductor layer;
a source electrode and a drain electrode over the second oxide semiconductor layer;
a gate insulating layer over the second oxide semiconductor layer; and
a gate electrode over the gate insulating layer,
wherein the first oxide semiconductor layer has a step portion, the step portion being thinner than a portion other than the step portion,
wherein a surface of the step portion is in contact with the source electrode and the drain electrode,
wherein an electron affinity of the first oxide semiconductor layer is higher than an electron affinity of the second oxide semiconductor layer, and
wherein an energy difference between a bottom of a conduction band of the first oxide semiconductor layer and a bottom of a conduction band of the second oxide semiconductor layer is 0.1 eV or more.

8. The semiconductor device according to claim 7, further comprising a first oxide insulating layer between the substrate and the first oxide semiconductor layer,
wherein the gate insulating layer comprises a second oxide insulating layer.

9. The semiconductor device according to claim 7,
wherein a constituent element of each of the first oxide semiconductor layer and the second oxide semiconductor layer is the same.

10. The semiconductor device according to claim 7,
wherein a side surface of the second oxide semiconductor layer is in contact with the source electrode and the drain electrode.

11. The semiconductor device according to claim 7,
wherein the step portion is located at an edge of the first oxide semiconductor layer.

12. An electronic device comprising the semiconductor device according to claim 7.

13. A semiconductor device comprising:
a third oxide semiconductor layer over a substrate;
a first oxide semiconductor layer over the third oxide semiconductor layer;
a second oxide semiconductor layer over and in contact the first oxide semiconductor layer;
a source electrode and a drain electrode over the second oxide semiconductor layer;
a gate insulating layer over the second oxide semiconductor layer; and
a gate electrode over the gate insulating layer,
wherein the first oxide semiconductor layer has a step portion, the step portion being thinner than a portion other than the step portion,
wherein a surface of the step portion is in contact with the source electrode and the drain electrode,
wherein an electron affinity of the first oxide semiconductor layer is higher than an electron affinity of each of the second oxide semiconductor layer and the third oxide semiconductor layer, and
wherein an energy difference between a bottom of a conduction band of the first oxide semiconductor layer and a bottom of a conduction band of each of the second oxide semiconductor layer and the third oxide semiconductor layer is 0.1 eV or more.

14. The semiconductor device according to claim 13, further comprising a first oxide insulating layer between the substrate and the third oxide semiconductor layer,
wherein the gate insulating layer comprises a second oxide insulating layer.

15. The semiconductor device according to claim 13,
wherein a constituent element of each of the first oxide semiconductor layer, the second oxide semiconductor layer and the third oxide semiconductor layer is the same.

16. The semiconductor device according to claim 13,
wherein a side surface of each of the second oxide semiconductor layer and the third oxide semiconductor layer is in contact with the source electrode and the drain electrode.

17. The semiconductor device according to claim 13,
wherein the step portion is located at an edge of the first oxide semiconductor layer.

18. An electronic device comprising the semiconductor device according to claim 13.
